(19) United States
(12) Patent Application Publication
(10) Pub. No.: US 2025/0221128 A1
(43) Pub. Date: Jul. 3, 2025

(54) DISPLAY DEVICES USING RECONSTITUTED SUBSTRATES AND METHODS OF FORMING THE SAME

(71) Applicant: Adeia Semiconductor Bonding Technologies Inc., San Jose, CA (US)

(72) Inventors: Rajesh Katkar, Milpitas, CA (US); Belgacem Haba, Saratoga, CA (US); Cyprian Emeka Uzoh, San Jose, CA (US); Guilian Gao, Campbell, CA (US); Thomas Workman, San Jose, CA (US)

(21) Appl. No.: 18/930,545

(22) Filed: Oct. 29, 2024

Related U.S. Application Data
(60) Provisional application No. 63/708,169, filed on Oct. 16, 2024.
(60) Provisional application No. 63/615,097, filed on Dec. 27, 2023.

(51) Int. Cl. H10H 29/41

(52) U.S. Cl. CPC H10H 29/41

(57) ABSTRACT

A display device comprises a first substrate and a second substrate. The first substrate includes a plurality of singulated control devices embedded in a first dielectric layer. The second substrate includes a plurality of singulated LEDs embedded in a second dielectric layer. The second substrate is directly bonded to the first substrate without an intervening adhesive.

### CROSS REFERENCE TO RELATED APPLICATIONS

This application claims the benefit of U.S. Provisional Patent Application No. 63/615,097, filed Dec. 27, 2023 and U.S. Provisional Patent Application No. 63/708,169, filed Oct. 16, 2024, each of which is hereby incorporated by reference herein in its entirety.

### FIELD

The present disclosure relates to displays and methods of manufacturing the same.

### BACKGROUND

Micro light emitting diode (microLED, micro-LED, μLED, or μ-LED) displays may provide benefits of higher resolution and increased brightness when compared to conventional display technologies. A typical microLED display may be a heterogeneous system that integrates microLEDs and control devices manufactured using different substrates and different process flows. Unfortunately, current manufacturing processes used to assemble separately manufactured microLEDs and control devices into a single display e.g., robot-aided pick-and-place processes, may be prohibitively expensive and time-consuming for most commercial applications. Accordingly, there exists a need in the art for improved microLED displays and methods of manufacturing the same.

### SUMMARY

Embodiments herein provide for manufacturing of display or display devices using reconstituted substrates. In some embodiments, the display is an LED display comprising LEDs of any suitable size such as greater than about 500 microns in size, equal to or less than about 500 microns in size, greater than about 100 microns in size, equal to or less than about 100 microns in size, equal to or less than about 50 microns in size, or equal to or less than about 5 microns in size. In some embodiments, the display or display device is a microLED display (e.g., comprising LEDs equal to or less than about 100 microns, 50 microns, or 5 microns in size). Advantageously, the displays and manufacturing methods described herein may provide for reduced manufacturing costs and manufacturing time compared to conventional manufacturing.

One general aspect includes a display or display device (e.g., LED display, microLED display) comprising a first substrate and a second substrate. The first substrate includes a plurality of singulated control devices embedded in a first dielectric layer. The second substrate includes a plurality of singulated light emitting devices (e.g., LEDs, microLEDs) embedded in a second dielectric layer. The second substrate is directly bonded to the first substrate without an intervening adhesive.

In some embodiments, each control device is electrically connected to one or more of the LEDs via direct hybrid bonds formed between the first substrate and the second substrate. Each control device and the one or more LEDs electrically connected thereto may form a pixel. Each pixel may include at least two or three LEDs that each emit a different color of light from the other.

In some embodiments, the display may further include a reflective layer disposed between each LED and the second dielectric layer. Portions of the reflective layer may be disposed between adjacent LEDs. In some embodiments, the display may further include a light absorbing layer comprising a light absorbing material that substantially reduces optical crosstalk between the adjacent LEDs. In some embodiments, the light absorbing layer is disposed between the reflective layer and the second dielectric layer. The second dielectric layer may include silicon oxide.

Another general aspect includes a display comprising a first substrate and a plurality of second substrates. The first substrate comprises a plurality of singulated control devices embedded in a first dielectric layer. The plurality of second substrates are arranged in a stack. Each second substrate is directly bonded to a vertically adjacent second substrate without an intervening adhesive. Each second substrate includes a plurality of singulated LEDs embedded in a respective second dielectric layer.

In some embodiments, the LEDs of each of the plurality of second substrates are horizontally offset with respect to the LEDs disposed in a vertically adjacent second substrate. Each control device may be electrically connected to one or more of the LEDs via direct hybrid bonds formed between the first substrate and an adjacent second substrates. Each control device and the one or more LEDs electrically connected to the control device may form a pixel. Each pixel may include at least three LEDs that each emit a different color of light from the others.

In some embodiments, a first reflective layer may be disposed between each LED and the second dielectric layer. Each pixel may include one or more light guides. Each light guide may include a second reflective layer that directs light emitted from a respective LED to a surface of the Display. Each of the one or more light guides may further include a dielectric fill disposed inward from the second reflective layer. The dielectric fill may have a higher optical transmission in a desired color spectrum than the second dielectric layer. The display may further include a light absorbing material layer disposed between the first reflective layer and the second dielectric layer. The second dielectric layer may include silicon oxide.

Another general aspect includes a display comprising a reconstituted substrate and a plurality of LEDs. The reconstituted substrate comprises a singulated control device embedded in a first dielectric layer. The plurality of LEDs are embedded in a second dielectric layer adjacent to and electrically connected to the control device.

In some embodiments, the control device and the plurality of LEDs form a pixel. Each pixel may include at least three LEDs that each emit a different color of light from the other.

In some embodiments, the display may further include a first reflective layer disposed between each LED and the dielectric layer. Portions of the first reflective layer may be disposed between adjacent LEDs. The display may further comprise a light absorbing material layer disposed between the first reflective layer and the second dielectric layer.

In some embodiments, the singulated control device includes an integrated circuit or a readout integrated circuit (ROIC) configured to control a collective luminous flux output of each pixel. The dielectric layer may include silicon oxide.

Another general aspect is a display including a first substrate and second substrates arranged in a stack. The first substrate and each second substrate include a plurality of singulated LEDs embedded in a respective dielectric layer. Each first substrate or second substrate is directly bonded to a vertically adjacent first substrate or second substrate without an intervening adhesive. The first substrate further includes a plurality of singulated control devices.

In some embodiments, the LEDs the first substrate and the second substrates are horizontally offset with respect to the LEDs disposed in a vertically adjacent first substrate or second substrate. At least one LED of each first substrate and second substrate may be electrically connected to the control device to form a pixel.

In some emboidments, the LEDs of the first substrate emit a different color of light from the LEDs of each second substrate. The display may further include a deep-trench-isolation that guides light emitted from the LEDs of at least of the first substrates or the second substrate to a surface of the display.

The display may further include a first reflective layer disposed between each LED and a respective dielectric layer. Each pixel may comprise one or more light guides. Each light guide may comprise a second reflective layer that directs light emitted from a respective LED to a surface of the display. Each of the one or more light guides may further include a dielectric fill disposed inward from the second reflective layer.

The dielectric fill may have a higher optical transmission in a desired color spectrum than the dielectric layer. The dielectric layer may include silicon oxide.

Another general aspect includes a method of forming a display. The method includes forming a first substrate comprising a plurality of singulated control devices embedded in a dielectric material. The method includes forming a plurality of second substrates. Forming each second substrate includes transferring a plurality of singulated LEDs to a carrier substrate, forming a reflective layer over the plurality of singulated LEDs, and forming a dielectric layer over the reflective layer. The method includes hybrid bonding the first substrate to the second substrate. Hybrid bonding electrically connects each control device to one or more LEDs of the second substrate to form a pixel.

Another general aspect includes a method of forming a display including transferring a plurality of singulated control devices and a plurality of singulated LEDs to a carrier substrate. The method includes forming a dielectric layer over the plurality of control devices and the plurality of LEDs. The method includes forming one or more a metal interconnect layers that electrically connect each control device to one or more LEDs.

In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

### BRIEF DESCRIPTION OF THE DRAWINGS

The above and other objects and advantages of the disclosure will be apparent upon consideration of the following detailed description, taken in conjunction with the accompanying drawings.

FIGS. 1A-1D schematically illustrate example views of a display, according to some embodiments;

FIGS. 2A-2B schematically illustrate example cross sectional views of a display, according to some embodiments;

FIGS. 3-6 schematically illustrate various embodiments of a display, according to some embodiments;

FIG. 7 schematically illustrates forming a portion of display, according to some embodiments;

FIGS. 8A-8B schematically illustrate hybrid bonding, according to some embodiments;

FIGS. 9A-9B schematically illustrate different views of an image sensor, according to some embodiments;

FIGS. 9C-9D schematically illustrate example pixel layouts of an image sensor, according to some embodiments;

FIGS. 10A-10C schematically illustrate example views of an image sensor, according to some embodiments;

FIGS. 11A-11B schematically illustrate example views of an image sensor, according to some embodiments;

FIG. 12 schematically illustrates forming a portion of an image sensor, according to some embodiments; and

FIG. 13 schematically illustrates various examples of an image sensor, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for improved (e.g., more efficient or high-volume) manufacturing of displays using reconstituted substrates or stacked and bonded reconstituted substrates. Each reconstituted substrate may include a plurality of singulated control devices and/or a plurality of singulated LEDs, where each control device is electrically connected to one or more of the LEDs to collectively form a pixel of the display.

The integration of microLED technology in displays may offer significant benefits in terms of resolution, energy efficiency, brightness, and overall display performance. The ability to precisely control each microLED may allow for better luminous flux with a higher dynamic range and a broader spectrum of colors, leading to more vibrant, bright, and lifelike images, which may be beneficial for applications requiring high-definition visuals, such as advanced televisions, smartphones, wearable devices, automotives, and virtual/augmented reality devices. Additionally, the energy efficiency of microLEDs may translate into longer battery life for portable devices and lower power consumption for larger displays. The versatility of microLED technology extends to the potential for flexible and transparent displays, opening new avenues for innovative design and application in various fields, ranging from consumer electronics to specialized industrial and medical equipment. MicroLED displays may have higher brightness, increased power efficiency, longer lifetime, more durability, and may be more suitable for stretchable and transparent display applications over light-crystal displays (LCD) or organic light emitting diode (OLED) displays.

However, microLED displays may be costly to fabricate and may have time-consuming manufacturing methods such as robot-aided pick-and-place processes used to transfer microLED chips from LED wafer(s) to a display substrate. As an example, a microLED ultra-high density (UHD) 4K RGB (red, green, blue) display may comprise about or at least 25 million microLEDs (e.g., about 8.3 million pixels with each pixel having at least a red microLED, a blue microLED, and a green microLED), and a die bonding machine may transfer between 5 to 10 microLEDs per second, taking approximately 700 hours to transfer 25 million microLED chips for a single display. Accordingly, there exists a need in the art for improved microLED displays with a streamlined mass transfer processes and the methods of manufacturing the same.

Advantageously, the displays or display devices (e.g., microLED displays) and manufacturing methods described herein may provide for reduced manufacturing costs and manufacturing time compared to conventional pick-and-place manufacturing.

A size of a pixel for a display may vary depending on the application-less than about 5 microns, less than about 10 microns, or about 5-10 microns for augmented reality/virtual reality (AR/VR) applications, about 40-60 microns or about 50 microns for cellphones, about 300-400 microns or about 350 microns for computer monitors and screens, and greater than about 0.5 mm for televisions. The size of the source LED occupying the pixel may not match the size of the pixel itself. Light emitted from a small LED can fill all of the pixel area of a large pixel and help create a continuous image. The ratio of pixel size to LED size can range from about 1.5 to 3 in AR/VR applications (e.g., pixel size is about 1.5× LED size to about 3× LED size) to over 100 (e.g., pixel size greater than about 100× LED size) in a television application. The smaller the ratio (e.g., area of pixel to area of LED), the larger the LED fill factor, and more light would be output. A larger LED fill factor indicates higher brightness requirement of the application. Different applications have varying luminous flux density requirement (e.g., brightness requirement). While AR/VR applications require extremely bright light so the projected images may be visible in extreme conditions (e.g., bright daylight), brightness requirements may be less stringent for other applications such as monitors and TVs in which the screens which have a larger viewing distance (e.g., are comparatively far away from an eye of a viewer). In some embodiments, a pixel comprises a plurality of source LEDs (e.g., an RGB pixel comprises 3 LEDs per pixel, an RGBG (red, green, blue, green) pixel comprises four LEDs per pixel), and a control circuit may be shared by several pixels.

The shorter the distance between the screen and viewer (e.g., an eye of a viewer) in an application, the smaller the pixel size requirement to provide a continuous image without a visible gap between the neighboring pixels. In AR/VR applications, where a display may be about 1-2 cm from an eye of a viewer, pixel sizes may be typically less than 5 microns, and there may be a challenge to achieve high pixel density and to ensure uniformity and brightness of pixels for an immersive visual experience. Such applications may require smaller pixels (e.g. <5-10 μm) and larger fill factor. The embodiments herein describe approaches which may enhance the density and uniformity of the pixels and/or improve the light emission efficiency. In television applications where pixel sizes can be greater than 0.5 mm (e.g., the screen is typically several feet away from the eye of a viewer; hence larger pixel and smaller LED fill factor would work), a stacked LED structure may be used for larger pixel requirements. In some embodiments, a pixel may include additional LEDs (e.g., other than RGB, such as white, cyan, etc.) to achieve an enhanced color gamut beyond the standard RGB and/or to add more light emission to improve brightness.

The reconstitution dielectric stacks may not be optimized for high optical transmission. The low-temperature oxide utilized in the reconstitution process, although optically transparent, may not meet optical grade standards, which could lead to scattering losses. The reconstituted wafer may incorporate several inorganic dielectric layers, including multiple layers of silicon oxide, silicon nitride, oxide, or nitride, etc. For instance, the refractive index of SiO₂ is about 1.96, whereas the refractive index of nitride is about 2.1. The refractive index value can vary based on factors such as the deposition process and temperature. An increase in the number of layers and interfaces can lead to greater reflective losses, especially for the light emitted at an angle to the dielectric layers.

In some embodiments, dielectrics specifically tuned to certain color spectrums may be used within the optical path of the display for improved efficiency. Suitable materials for these dielectrics may include polystyrene, cyclic olefin polymer/cyclic olefin copolymers, polycarbonate, PMMA (Acrylic), or Ultraviolet Acrylic. These materials are known for their high transmission in the visible spectrum, which is relevant for improved efficiency and functionality of an RGB display.

As described below, semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

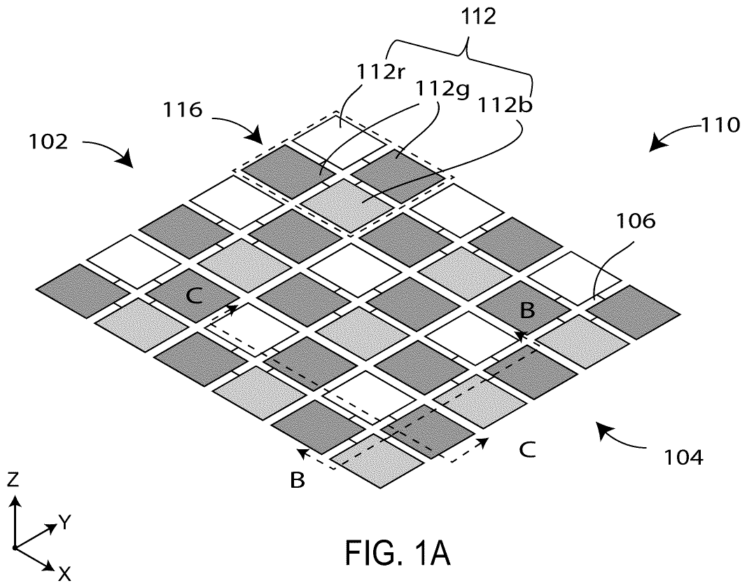

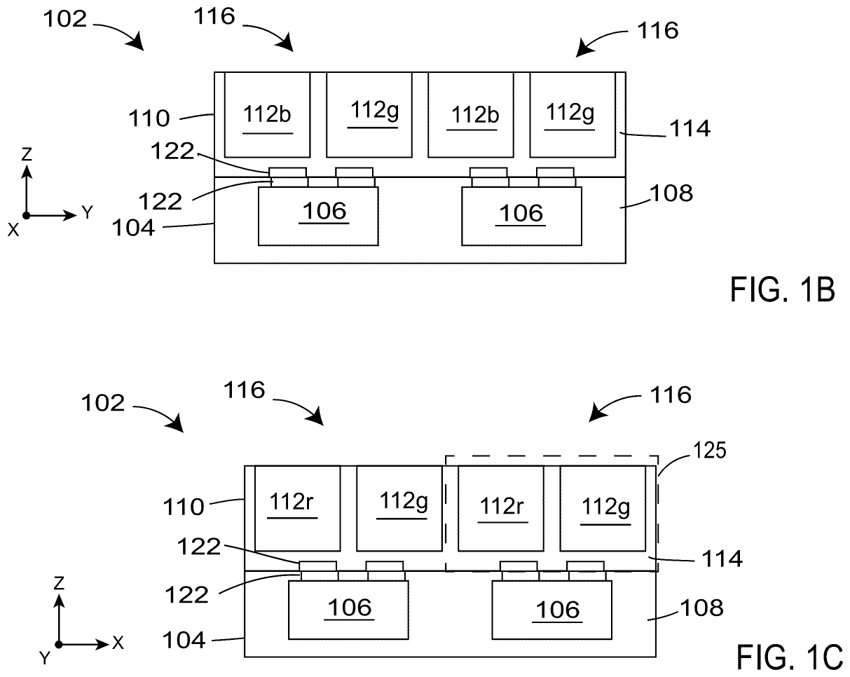

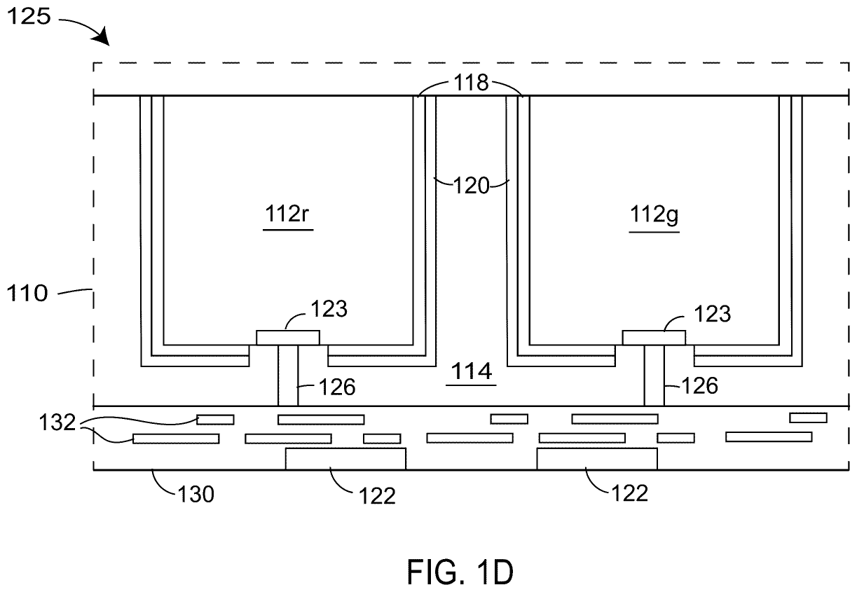

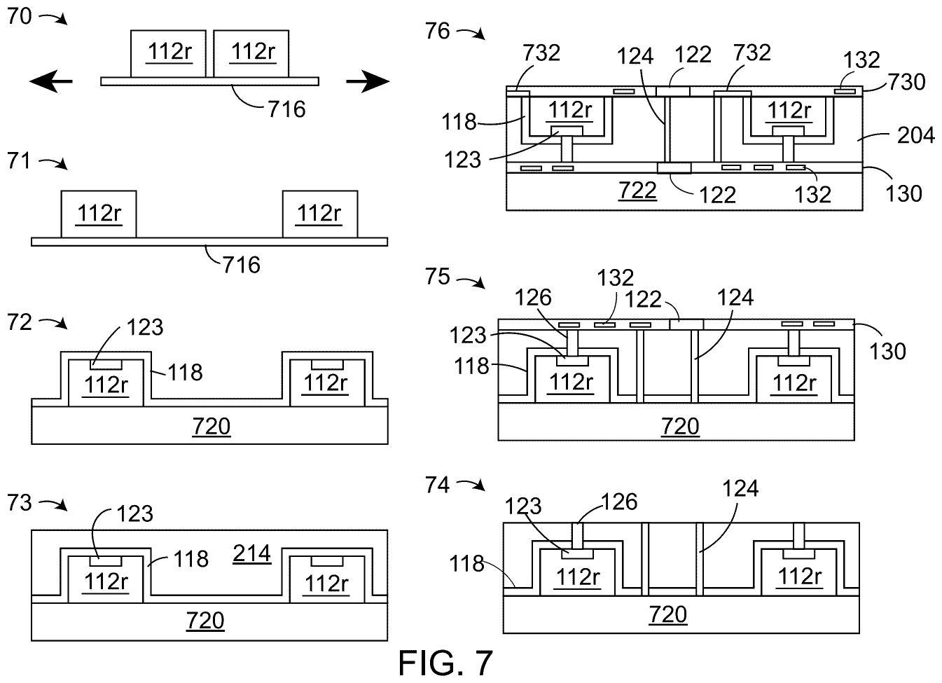

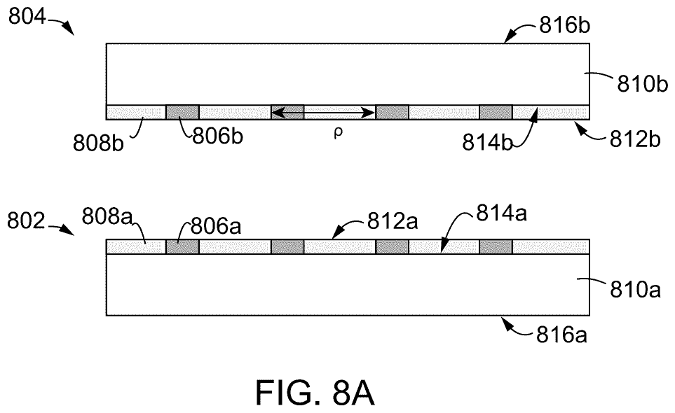

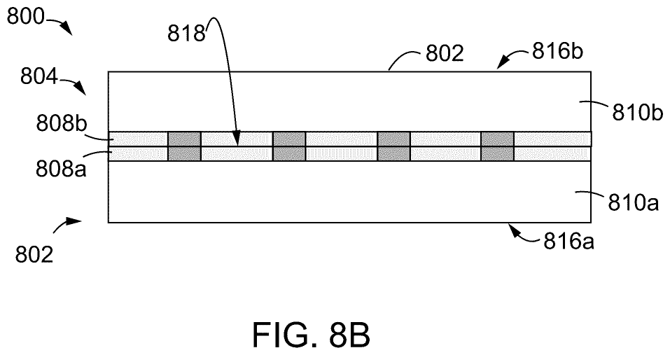

FIGS. 1A-1D, 2A-2B, 3, 4, 5, and 6 schematically illustrate various embodiments of a display. The display may comprise LEDs 112 (e.g., red LEDs 112r, green LEDs 112g, blue LEDs 112b). In some embodiments, the display may be a microLED display. For example, the LEDs 112 may be microLEDs, with sizes equal to or less than about 100 microns, 50 microns, or 5 microns. FIG. 7 details the method used for spacing LEDs in preparation for a stackable, heterogeneous reconstitution. FIGS. 8A-8B illustrate a hybrid bonding method for bonding substrates (e.g., substrates comprising LEDs to substrates comprising LEDs, substrates comprising LEDs to substrates comprising control devices and/or LEDs).

In some embodiments, the display (e.g., display 102, display 202, display 302, display 402, display 502, display 602, or any suitable display described throughout the present disclosure) may be an LED display and comprise LEDs greater than about 500 microns in size, or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

FIG. 1A presents a top-down, isometric view of the pixel layout in a display 102, in accordance with some embodiments of the present disclosure. The display 102 comprises a plurality of singulated control devices 106 in a first substrate 104, each being electrically connected to one or more LEDs 112 in a second substrate 110. This connection is facilitated through direct hybrid bonds between the first substrate 104 and the second substrate 110. Each control device 106, along with its connected one or more LEDs 112, forms a pixel 116. Each pixel 116 may comprise at least two LEDs 112, each emitting a distinct color of light. For a color display, each pixel may comprise three colors or three LEDs, each capable of emitting a different color (e.g., red (R), green (G), and blue (B)). In some embodiments, a color display may include a fourth color like cyan (C) or magenta (M).

As shown in FIG. 1A, the pixel 116 comprises four LEDs, e.g., two green LEDs 112g, one blue LED 112b, and one red LED 112r. This configuration may be used as the spectral sensitivity of human eye is strongest for green light (e.g., for a better visual experience, it may be better to have more green LEDs in a display). This configuration may also be used due to the lower efficiency of gallium (Ga) based phosphors in emitting green light compared to red or blue. In larger displays with bigger pixels, more high-intensity LED light sources may be accommodated within a single pixel. To further enhance the color gamut beyond that of a traditional RGB display, LEDs having a small size enable possibility of including more than three LEDs within each pixel.

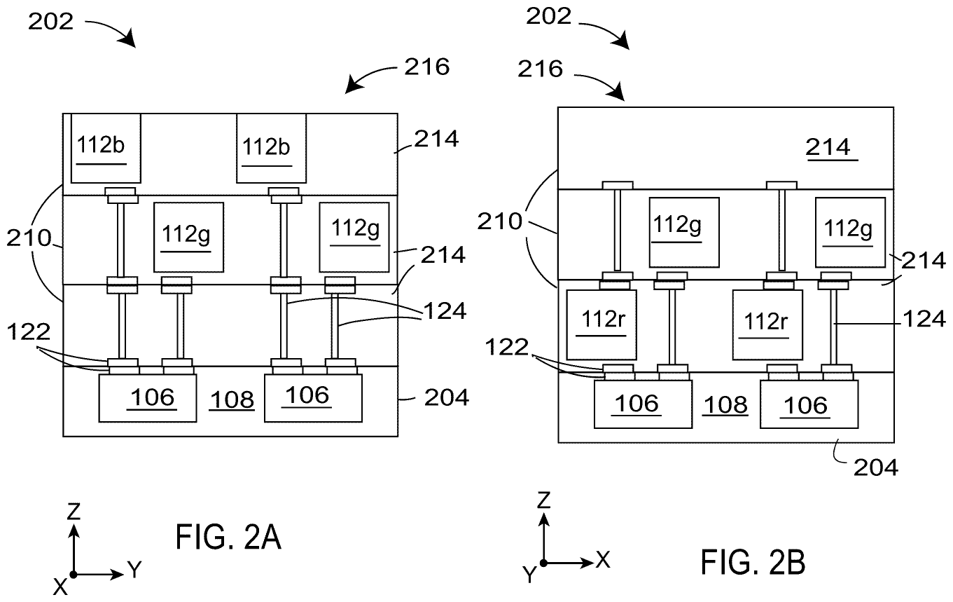

Although the display 102 of FIG. 1A and other displays of the present disclosure (e.g., display 202 of FIGS. 2A-2B) may show a pixel (e.g., pixel 116 of FIG. 1A, pixel 216 of FIGS. 2A-2B) comprising four LEDs with two green LEDs 112g, one red LED 112r, and one blue LED 112b, a pixel may comprise any suitable number of LEDs (e.g., 1, 2, 3, 4, 5 or more LEDs) and colors (e.g., 1, 2, 3 or more colors). For example, a pixel may comprise four LEDs with four colors such as a red, green, blue and cyan LED.

In FIG. 1A, lines B-B and C-C, depicted as dotted lines, overlap the top of the display 102. Line B-B runs parallel to the y-axis and indicates the cross-sectional direction for FIG. 1B. Line C-C, orthogonal to B-B and parallel to the x-axis, corresponds to the cross-sectional direction for FIG. 1C. FIGS. 1B and 1C provide illustrative cross-sectional schematics that further detail the reconstituted layers of the display 102.

FIGS. 1B and 1C depict a display 102, which includes a first substrate 104. The first substrate 104 comprises a plurality of singulated control devices 106 disposed in a first dielectric layer 108. In some embodiments, a control device 106 may be a readout integrated circuit (ROIC), that regulates the collective luminous flux output of each pixel. In some embodiments, the control device 106 may be a processor or controller. In some embodiments, a footprint of the control devices 106 may be larger or smaller than a footprint of an LED 112. Although, FIG. 1B and FIG. 1C depict multiple control devices 106 (e.g. dies) embedded or disposed in a dielectric layer 108 that forms a first substrate 104 (e.g., reconstituted substrate or wafer), in another embodiment the first substrate 104 may comprise a wafer (e.g., ROIC wafer or full wafer).

The display 102 further includes a second substrate 110 directly bonded to the first substrate 104 without an intervening adhesive. The second substrate 110 comprises a plurality of singulated LEDs 112 (e.g., red LEDs 112r, green LEDs 112g, blue LEDs 112b) disposed in a second dielectric layer 114.

The first substrate 104 and the second substrate 110 may comprise any suitable substrate such as those mentioned in the present disclosure. For example the first substrate 104 and/or the second substrate may comprise dummy substrates, passive interposers, silicon wafers, passive optical elements (e.g., glass substrates, gratings, lenses), or materials used for base substrate portions 810a, 810b as described in reference to FIG. 8.

The first dielectric layer 108 and the second dielectric layer 114 each comprise a dielectric material. The first dielectric layer 108 and the second dielectric layer 114 may comprise a same material or different materials. The dielectric material may be any suitable dielectric material such as dielectric materials mentioned in the present disclosure. For example dielectric material may comprise oxides, nitrides, oxynitrides, carbonitrides, and oxycarbonitrides, silicon oxide, silicon nitride, silicon oxynitride, silicon carbonitride, silicon oxycarbonitride, non-conductive material such as a dielectric material or an undoped semiconductor material, such as undoped silicon, which may include native oxide, silicon oxide, silicon nitride, silicon carbide, low K dielectric materials, SiCOH dielectrics, diamond-like carbon or a material comprising a diamond surface. For example the first dielectric layer 108 and second dielectric layer 114 may comprise materials used for bonding layer 808a and 808b of FIG. 8B.

Each control device 106 is electrically connected to one or more of the LEDs 112 via direct hybrid bonds formed between the first and second substrates (e.g., bonding of conductive features or bond pads disposed in respective dielectric layers). Additional detail regarding hybrid bonds and hybrid bonding of substrates may be found in the present disclosure, e.g., at least at the description of FIGS. 8A and 8B. Although, FIG. 1B and FIG. 1C depicts multiple control devices 106 (e.g. dies) embedded or disposed in a dielectric layer 108 to form a reconstituted substrate or wafer (e.g., first substrate 104), some embodiments may have one or more LEDs 112 in second substrate 110 hybrid bonded to a wafer (e.g., control or controller device wafer, a device wafer, ROIC wafer, or full wafer in place of the first substrate 104).

Each control device 106, along with the electrically connected LEDs 112, forms a pixel 116. As indicated earlier, FIG. 1B is a cross-sectional view taken along the y-axis, revealing pixels embedded in the top layer with alternating LEDs 112 of green and blue colors (e.g., green LED 112g and blue LED 112b). Orthogonally, FIG. 1C displays alternating LEDs 112 of green and red colors (e.g., green LED 112g and red LED 112r). The staggering of LEDs 112 in alternating colors, as depicted in FIGS. 1B and 1C, may enhance the overall color rendering and uniformity of the display 102. This arrangement may enable each pixel to produce a wider range of colors with higher fidelity, contributing to a more vibrant and accurate visual output. By alternating colors like green and blue, or green and red, in adjacent LEDs 112, the display 102 may effectively manage blending of colors at the pixel level. The staggering of LEDs 112 may be applied to any suitable display such as those described in embodiments of the present disclosure (e.g., display 302, display 402, display 502, display 602, etc.).

In FIG. 1C, a dotted box 125 highlights a zoomed-in view of a portion of the display 102, as shown in FIG. 1D. For example, FIG. 1D shows detailed features such as a reflective layer 118, light absorbing layer 120, electrodes 123, connectors 126, and redistribution layer 130 comprising interconnects 132 that include conductive wiring and conductive vias. The features shown in FIG. 1D may be applied to any suitable display (e.g., display 202, display 302, display 402, display 502, display 602, or any display described in embodiments of present disclosure).

FIG. 1D illustrates a detailed view of the dotted box 125 where sections of a reflective layer 118 is disposed between adjacent LEDs 112. The reflective layer 118 is disposed or positioned between each LED 112 and the second dielectric layer 114. The reflective layer 118 may comprise a reflective material (e.g., a metal material such as aluminum (Al) silver (Ag) or gold (Au), etc. or a combination thereof). In some embodiments, the reflective layer 118 may comprise distributed Bragg Reflector (DBR) coatings. The inclusion of the reflective layer 118 may enhance the luminance of the light output from the surface of the display and may also be used to prevent optical cross talk between LEDs 112. When electrical current flows through a LED 112, incoherent light is emitted in all directions. A reflective layer 118 enables light emitted towards the reflective layer 118 to be directed towards a viewing surface of the display 102. For example, the reflective layer 118 reflects light emitted from the LEDs 112 back towards a viewing surface of the display 102, increasing the brightness and contrast of the display 102. In some embodiments, a reflective layer 118 is used in applications where high visibility is relevant, such as outdoor displays or high-definition screens. The reflective layer 118 may serve as a protective barrier for the LEDs 112 from environmental factors and may extend the lifespan of the display. In some embodiments, shape the non-horizontal wall (e.g., sidewalls) of the reflector layer may comprise a parabolic or hyperbolic shape for a parabolic or hyperbolic reflector.

In some embodiments, a light-absorbing layer 120 may be disposed or positioned between adjacent LEDs 112. The light-absorbing layer 120 comprising a light-absorbing material may be disposed between the reflective layer 118 and second dielectric layer 114. The light-absorbing material may significantly reduce optical crosstalk between neighboring LEDs 112. In some embodiments, the light-absorbing material comprises a metallic, resin, or polymer material.

In some embodiments, the second substrate 110 comprising a plurality of singulated LEDs 112 disposed in a second dielectric layer 114, may include an interconnect layer or redistribution layer 130, such as a redistribution layer (RDL). The electrodes 123 of the LEDs 112 are electrically connected to conductive features (e.g., bond pads 122) via connectors 126 through interconnects 132 in the interconnect layer or redistribution layer 130. The bond pads 122 embedded in the second dielectric layer 114, can be hybrid bonded to bond pads 122 of control device 106 (e.g., a processor or controller, ROIC, etc.) embedded, in some embodiments, in the layer below what is shown in FIG. 1D. The bond pads 122, electrodes 123, connectors 126, and interconnects 132 may comprise any suitable conductive material. For example, a conductive material may include metals such as copper or copper alloys, nickel, aluminum, or alloys, conductive oxide material such as indium tin oxide (ITO).

FIGS. 2A and 2B depict cross-sectional views of a display 202. The cross-section in FIG. 2A is taken along the y-axis, while the cross-section in FIG. 2B is taken along the x-axis as shown in FIG. 1A. The display 202 comprises a stack of substrates including a first substrate 204 and a plurality of second substrates 210. The first substrate 204 is directly bonded (e.g., hybrid bonded) to a vertically adjacent second substrate 210, without any intervening adhesive. Each second substrate 210 is directly bonded (e.g., hybrid bonded) to a vertically adjacent second substrate 210, without any intervening adhesive.

In some embodiments, the first substrate 204 of FIGS. 2A-2B is similar or the same as first substrate 104 of FIGS. 1A-1D. The first substrate 204 comprises a plurality of singulated control devices 106 embedded within a first dielectric layer 108. Each control device 106 is electrically connected to one or more of the LEDs 112 via direct hybrid bonds formed between the first substrate 204 and second substrates 210 (e.g., bonding of conductive features or bond pads disposed in respective dielectric layers). Additional detail regarding hybrid bonds and hybrid bonding of substrates may be found in the present disclosure, e.g., at least at the description of FIGS. 8A and 8B. In some embodiments, in place of the first substrate 204 comprising multiple control devices 106 (e.g. dies) embedded or disposed in a dielectric layer 108 (e.g., reconstituted substrate or wafer), the first substrate 204 may comprise a wafer (e.g., control or controller device wafer, device wafer, ROIC wafer, or a full wafer).

In some embodiments, the second substrates 210 of FIGS. 2A-2B may be similar to second substrate 110 of FIGS. 1A-1D in that the second substrates include a plurality of singulated LEDs 112 disposed in a respective second dielectric layer (e.g., dielectric layer 114 or dielectric layer 214). However, each second substrate 210 of FIGS. 2A-2B comprises LEDs that emit a same color light (e.g., reconstituted red LED substrate, reconstituted blue LED substrate, and reconstituted green LED substrate) while a second substrate 110 of FIGS. 1A-1D comprise LEDs that emit light of different colors (e.g., a reconstituted substrate with red, green, and blue LEDs).

In some embodiments, dielectric layer 214 of FIGS. 2A-2B may be similar to dielectric layer 114 of FIGS. 1A-1D. In some embodiments, dielectric layer 214 of FIGS. 2A-2B may be different than dielectric layer 114 of FIGS. 1A-1D. For example, in display 102, light emitted from LEDs 112 may not be transmitted through the second dielectric layer 114 before exiting a viewing surface of the display, whereas light emitted from LEDs 112 of display 202 may emitted through the second dielectric layer 214 before exiting a viewing surface of the display. In some embodiments, the second dielectric layer 214 may include silicon oxide (SiO₂), silicon nitride (Si₃N₄), doped silicon oxide for better optical transmission or polymers for the same. In some embodiments, the second dielectric layer 214 of different second substrates 210 comprise a same material. In some embodiments, the second dielectric layer 214 of different second substrates 210 comprise a different material. In some embodiments, first or second dielectric layers 214 may comprise more than one layer of a same dielectric material or different dielectric materials.

As shown in FIGS. 2A-2B, a top second substrate 210 comprises blue LEDs 112b, a middle or intermediate second substrate 210 comprises green LEDs 112g, and a bottom second substrate 210 comprises red LEDs 112r. Although display 202 shows the second substrates 110 having LEDs of a particular color in a particular layer, a display may have any suitable arrangement of stacked second substrates (e.g., top second substrate 210 comprises red LEDs 112r, intermediate second substrate 210 comprises green LEDs 112g, and bottom second substrate 210 comprises blue LEDs 112b, etc.).

In the display 202, the LEDs 112 on each second substrate 210 are horizontally offset relative to the LEDs 112 in the vertically adjacent second substrate 210. Each control device 106 is electrically connected to one or more LEDs 112 via direct hybrid bonds formed between the first substrate 204 and the adjacent second substrates 210. Each control device 106, along with the connected LEDs 112, forms a pixel 216. These pixels 216 comprise at least three LEDs (e.g., green LED 112g, blue LED 112b, and red LED 112r), each emitting a distinct color of light, such as green, blue, and red.

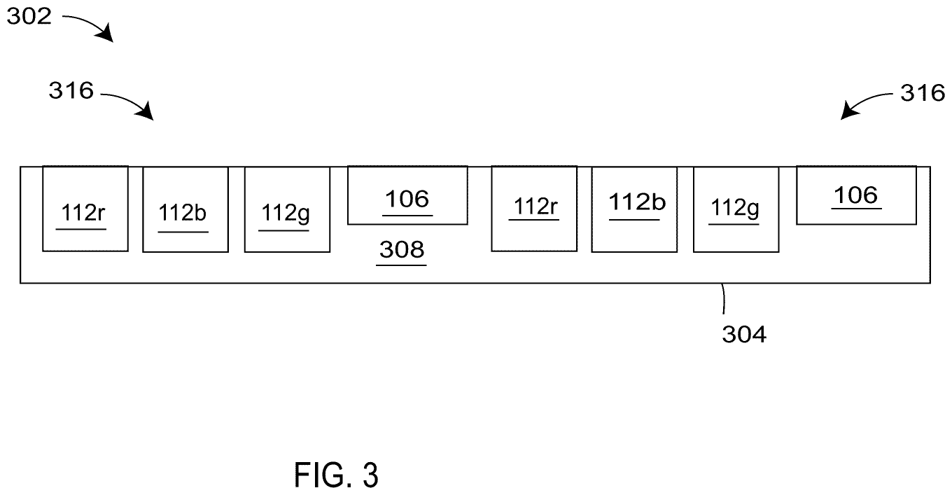

FIG. 3 illustrates a cross-sectional schematic of a display 302, where the singulated LEDs 112 and control devices 106 are reconstituted in a same layer. The display 302 comprises a reconstituted substrate 304. The reconstituted substrate 304 comprises singulated control devices 106 disposed in a dielectric layer 308, alongside a plurality of LEDs 112. In some embodiments, the dielectric layer 308 of FIG. 3 is similar to the first dielectric layer 108 of FIGS. 1A-1D. In some embodiments, instead of a display comprising a reconstituted substrate 304, the display may comprise bonded substrates, where at least one of the substrates is a reconstituted substrate. For example, a display may comprise a first reconstituted substrate bonded to a second reconstituted substrate. The first reconstituted substrate or wafer may comprise singulated RGB LEDs embedded or disposed in a first dielectric layer (e.g., similar to the reconstituted substrate 304 but not including control devices 106). The second reconstituted substrate or wafer may comprise singulated control devices 106 embedded or disposed in a second dielectric layer (e.g., similar to first substrate 304 but not including the LEDs 112). In another example, a display may comprise a reconstituted substrate bonded to a wafer (e.g., control or controller device wafer, device wafer, ROIC wafer, or full wafer). For example, the reconstituted substrate or wafer may comprise singulated RGB LEDs embedded or disposed in a dielectric layer (e.g., similar to the reconstituted substrate 304 but not including control devices 106).

Each pixel 316 comprises at least three LEDs 112, each emitting light in a different color, such as green, blue, and red. For example, a control device 106 may be electrically connected to three LEDs (e.g., red LED 112r, blue LED 112b, and green LED 112g) to form a pixel 316. The LEDs 112 are disposed in the dielectric layer 308 adjacent to, and electrically connected with, the control device 106. In some embodiments, a control device 106 may be connected to red LEDs, green LEDs, and blue LEDs from different pixels. For example, each pixel may include a red, green, and a blue LED, and a control device 106 may be connected to or control several pixels (e.g., 2, 3 or more, etc.). For example a control device may be connected to or control two pixels (e.g., a first red LED, first green LED, first blue LED, a second red LED, second green LED, and second blue LED).

Although FIG. 3 may illustrate a pixel 316 comprising three LEDs (e.g., red LED 112r, blue LED 112b, and green LED 112g) electrically connected to a control device 106, pixel 316 may comprise any suitable arrangement, number, and color of LEDs. For example, a pixel may comprise four LEDs electrically connected to a control device, the control device 106 may be centrally located between the LEDs (e.g., 1D arrangement of red LED 112r, green LED 112g, control device 106, blue LED 112b, green LED 112g or a 2D arrangement of a control device 106 being surrounded on all sides by LEDs).

In some embodiments, any suitable display (e.g., display 102, display 202, display 402, display 502, display 602, or displays described in embodiments of present disclosure) may have an arrangement of LEDs 112 each LED has a neighboring LED of a different color, or where rows or columns of LEDs are a same color. In some embodiments, each LED may have a neighboring LED of a different color. For example, LEDs of three colors may be shifted in adjacent rows so that each LED has a neighboring pixel of a different color (e.g., first row-GBRGBR, second row: RGBRGB, third row: BRGBRG). In some embodiments, each row or column of LEDs may include LEDs of a same color. For example, rows of a display include LEDs have a same color (e.g., row of red LEDs, green LEDs, and blue LEDs), and a pixel comprises a portion of a column of LEDs (e.g., RGB LEDs, RGBG LEDs). In some embodiments, columns of LEDs include LEDs of a same color (e.g., column of red LEDs, green LEDs, and blue LEDs), and a pixel comprises a portion of a row of LEDs (e.g., RGB LEDs, RGBG LEDs).

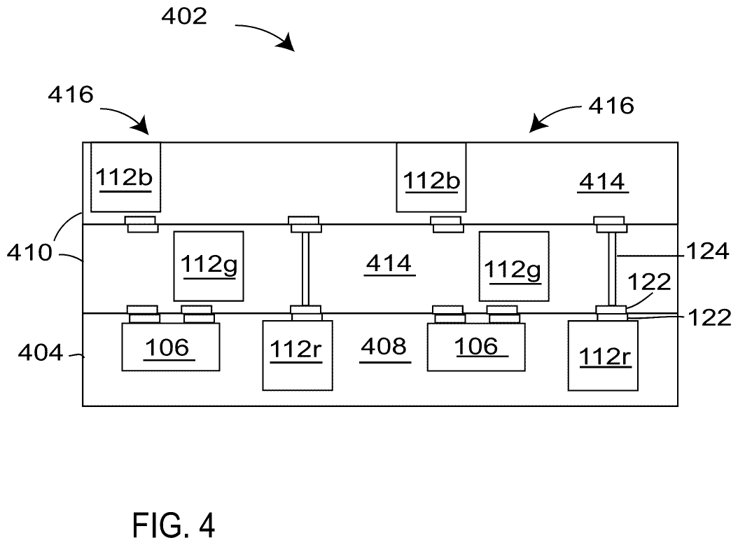

FIG. 4 illustrates a cross-section of a stacked display 402, which includes three stacked layers. The display 402 includes a first substrate 404 and two second substrates 410, arranged in a stack. The first substrate 404 comprises a plurality of singulated control devices 106 and singulated LEDs 112 disposed in a first dielectric layer 408. In some embodiments, each control device 106 is electrically connected to one or more of the LEDs 112 via direct hybrid bonds formed between the first substrate 204 and second substrates 210 (e.g., bonding of conductive features or bond pads disposed in respective dielectric layers). Additional detail regarding hybrid bonds and hybrid bonding of substrates may be found in the present disclosure, e.g., at least at the description of FIGS. 8A and 8B. In some embodiments, each control device 106 may be connected to one or more corresponding LEDs (e.g., red LED 112r) through interconnects in substrate 404 and one or more corresponding LEDs (e.g., blue LED 112b, green LED 112g) via direct hybrid bonds. For example, conductive features, bond pads, routing, or interconnects at the interface between first substrate 404 and second substrate 410 make electrical connections between the control device 106 and corresponding LEDs. In some embodiments, a control device 106 may be electrically connected to several LEDs in the first substrate 204 via a routing layer and several LEDs in the second substrates 210 via routing layers hybrid bonded interconnects. For example, routing layers may disposed at bond interfaces. In some embodiments, a routing layer may comprise a separate layer formed on a reconstituted substrate or wafer to enable hybrid bonding. In some embodiments, a control device 106 may be connected to or control one pixel. For example, a pixel may include a red LED, a green LED, and a blue LED, and a control device 106 may be connected to or control a red LED, a green LED, and a blue LED. In some embodiments, a control device 106 may be connected to or control several pixels. For example, each pixel may include a red, green, and a blue LED, and a control device 106 may be connected to or control several pixels (e.g., 2, 3 or more, etc.). For example a control device may be connected to or control two pixels (e.g., a first red LED, first green LED, first blue LED, a second red LED, second green LED, and second blue LED).

In some embodiments, first dielectric layer 408 of FIG. 4 may be similar to first dielectric layer 108 of FIGS. 1A-1D. In some embodiments, dielectric layer 408 of FIG. 4 may be different than dielectric layer 108 of FIGS. 1A-1D.

In some embodiments, the two second substrates 410 comprise a plurality of singulated LEDs 112. The second substrates 410 of FIG. 4 may be similar to second substrates 210 of FIGS. 2A-2B. For example, second substrates 410 comprises LEDs 112 disposed in a respective dielectric layer 414. As shown in FIG. 4, the top second substrate 410 comprises a plurality of blue LEDs 112b, and the bottom second substrate 410 comprises a plurality of green LEDs 112g.

In some embodiments, any suitable arrangement of LEDs in the first substrate 404 and second substrates 410 may be used. The first substrate 404 and/or the second substrates 410 may comprise any suitable LED (e.g., blue LED 112b, green LED 112g, or LED emitting any suitable color) disposed in a respective dielectric layer. For example, the top second substrate 410 may comprise a plurality of red LEDs 112r, and the first substrate 404 may comprise a plurality of singulated blue LEDs 112b.

Although two second substrates 410 are shown, any suitable number of second substrates 410 (one, three or more) in any suitable arrangement may be used. Each of these substrates may be directly bonded to a vertically adjacent substrate (e.g., a first substrate 404 or a second substrate 410) without any intervening adhesive.

In some embodiments, the LEDs 112 on the first substrate 404 and the second substrates 410 are horizontally offset relative to the LEDs 112 situated in a vertically adjacent substrate. At least one LED 112 from each substrate is electrically connected to a control device 106, thus forming a pixel 416. The LEDs 112 on the first substrate 404 emit light in a different color than those on each of the second substrates 410.

In some embodiments, the control device 106 may be overlapping in a vertical direction with one or more singulated LEDs. For example, a footprint of the control device 106 may overlap, partially or fully, with a footprint of one or more singulated LEDs (e.g., blue LED 112b, green LED 112g in FIG. 4). In some embodiments, a singulated LED may cover the control device (e.g. the footprint of a control device may fit within a footprint of a singulated LED when viewed from bottom up or top down). In some embodiments, a footprint of a singulated LED may be smaller than a footprint of a control device 106. In some embodiments, elements such as vias, bond pads, electrodes, and interconnects in a lower layer may overlap a singulated LED in an upper layer. For example, elements (e.g., vias 124) in a second substrate (e.g., second substrate 410) may be positioned so their footprint is beneath a singulated LED (e.g., blue LED 112b). An LED may cover elements corresponding the LED used to pass signals to/from the LED through second substrates to a control device in a first substrate.

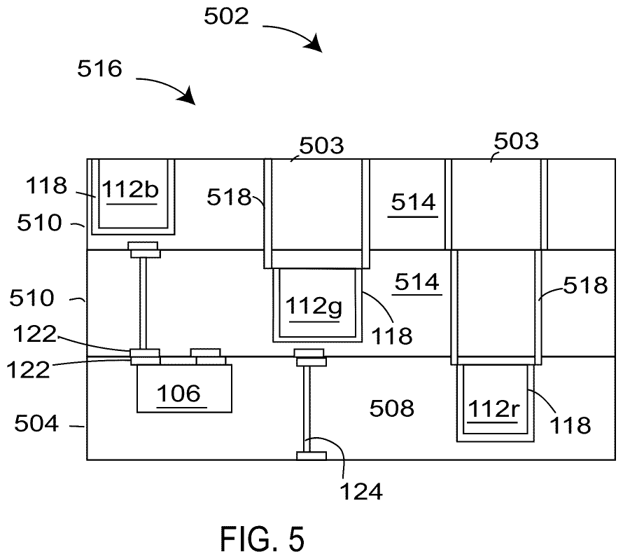

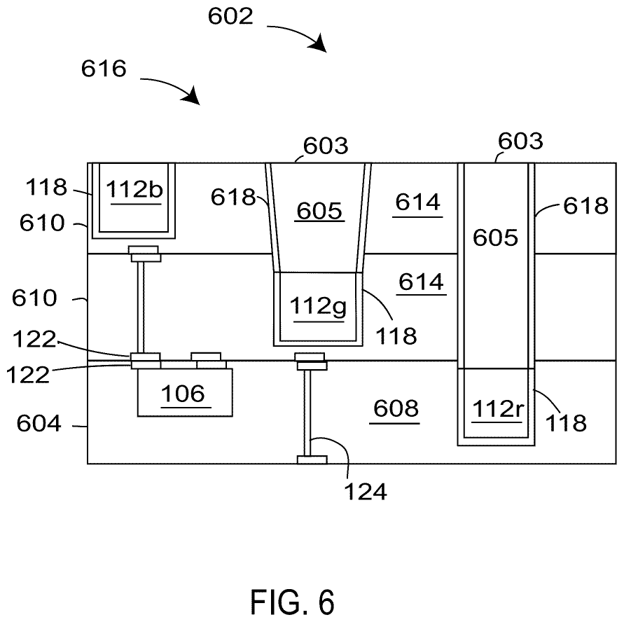

FIGS. 5 and 6 show cross-sections of a stacked display with light guides. The display 502 and 602 may be same or similar to the display 402 shown in FIG. 4, with the addition of light guides (e.g., light guides 503 or light guides 603). FIG. 5 shows example light guides 503 made by using deep trench isolation (DTI) techniques at a wafer level (e.g., forming deep trenches for isolation and filling the trenches with a reflective material or reflective layer 118. For example, the reconstitution dielectric is part of the light guide 503 as the reflective layer 118 directs light from a corresponding LED through the reconstitution dielectric. FIG. 6 shows example light guides 603 made by forming isolation channels with a reflective coating, before or after wafer-to-wafer (W2W) bonding. In some embodiments, the reconstitution dielectric may be opaque, semi-transparent or comprise of in-homogeneous material (e.g. epoxy mold compound with silica fillers). For example, as the isolation channels are formed by removing portions of the reconstitution dielectric in a region corresponding to light emission area from a respective LED, the reconstitution dielectric may be opaque. In some embodiments, the isolation channels with the reflective coating deposited on the sidewalls of the channels, may be subsequently filled with a transparent dielectric material.

FIG. 5 illustrates a cross-section of a stacked display 502, which includes three stacked layers. The display 502 includes a first substrate 504 and two second substrates 510, arranged in a stack. The first substrate 504 comprises a plurality of singulated control devices 106 and singulated LEDs 112 (e.g., red LEDs 112r) disposed in a first dielectric layer 508. The second substrates 510 comprises singulated LEDs (e.g., green LEDs 112g, blue LEDs 112b) disposed in a respective second dielectric layer 514. In some embodiments, each control device 106 is electrically connected to one or more of the LEDs 112 via direct hybrid bonds formed between the first substrate 504 and second substrates 510 (e.g., bonding of conductive features or bond pads disposed in respective dielectric layers). At least one LED 112 from each substrate is electrically connected to a control device 106, thus forming a pixel 516.

Each pixel 516 in the display 502 includes one or more light guides 503. Each LED 112 has a first reflective layer 118 adjacent to LED 112. Each light guide 503 is adjacent to a reflective layer 518 (e.g., second reflective layer) used to guide light emitted from a respective LED 112 to the surface of the display 502. The light guides 503 in the reconstitution dielectric (e.g., second dielectric layer 214) may increase intensity output performance of the display 502.

In some embodiments, monochromatic wafers may be reconstituted and stacked, and deep trench isolation may be formed in the passive parts of the chip or wafer to minimize or reduce scattering and noise. Low-temperature dielectric or polymeric dielectric used for reconstitution (e.g., SiO₂) may not be an optical grade oxide, and may not allow for high transmission in the visible spectra, having a high absorption loss. Deep trench isolation and the light guides 503 may enable light to circumnavigate face-to-face surface interfaces of the stack where there may be additional Fresnel losses.

In some embodiments, at the wafer level, deep trench isolation may be formed and filled with reflective coatings. For example, deep trench isolation may be an opening in which reflective material is filled to form the reflective coating or reflective layer 518. In some embodiments, the opening may be drilled, cut, or etched at the wafer level. The deep trench isolation may be formed before wafer bonding and may have a box-like appearance. The waveguides (e.g., light guides 503) may have different width or radius. As shown on the right of FIG. 5, the light guide 503 on top of LED 112r with different width or radius in different wafer levels may be formed using deep trench isolation prior to wafer bonding and filled with reflective material. The waveguides (e.g., light guides 503) may have a same width or radius. For example, as shown in the middle of FIG. 5, the light guide 503 on top of LED 112g with same width or radius in different wafer levels may be formed after bonding, using deep trench isolation and filled with reflective material. In some embodiments, the exposed sidewall of the wave guide 503 may be coated with reflective material (not shown). In some embodiments, the reflective material of the wave guide 503 may be coated with an optically transparent protective coating (not shown). In some embodiments, the reflective material and protective coating may or may not comprise the same material composition.

FIG. 6 illustrates a cross-section of a stacked display 602, which includes three stacked layers. The display 602 includes a first substrate 604 and two second substrates 610, arranged in a stack. The first substrate 604 comprises a plurality of singulated control devices 106 and singulated LEDs 112 (e.g., red LEDs 112r) disposed in a first dielectric layer 608. The second substrates 610 comprises singulated LEDs (e.g., green LEDs 112g, blue LEDs 112b) disposed in a respective second dielectric layer 614. In some embodiments, each control device 106 is electrically connected to one or more of the LEDs 112 via direct hybrid bonds formed between the first substrate 604 and second substrates 610 (e.g., bonding of conductive features or bond pads disposed in respective dielectric layers). At least one LED 112 from each substrate is electrically connected to a control device 106, thus forming a pixel 616.

FIG. 6 shows a cross-section of a stacked display 602. To reduce or minimize scattering losses, isolation channels with reflective coating may be formed either before or after W2W bonding. The display 602 shows each pixel 616 includes one or more light guides 603, each light guide comprising a second reflective layer 618 that directs light emitted from a respective LED 112 to a surface of the display 202. In some embodiments, the isolation channels may not be filled with any material. The isolation channels may be created and reflective coating deposited on the sidewalls, and the channels may be subsequently filled with a transparent dielectric. In some embodiments, the reconstitution dielectric is opaque. In some embodiments, isolation channels may be formed after wafer bonding and the sidewall of the waveguide may have a sloped appearance (e.g., waveguide corresponding to green LED 112g).

In some embodiments, the isolation channels may be filled with a dielectric material that is disposed inward from the second reflective layer 618. The dielectric material may be disposed inward from the second reflective layer 618 and may have a higher optical transmission in a desired color spectrum than the dielectric layer 608. For example, a dielectric fill for an isolation channel above a particular color LED (e.g., red, green, blue) may have a higher optical transmission in the corresponding color wavelength range (e.g., red wavelength range, green wavelength range, blue wavelength range, respectively). In some embodiments the dielectric layer 608 and/or the dielectric layer 214 comprises silicon oxide. The dielectric fill 605 may have a higher optical transmission in a desired color spectrum than the second dielectric layer 214.

In some embodiments the first substrate 604 or 504, or any other first substrate (e.g., first substrate 104, first substrate 204, first substrate 404, etc.) may include a via 124 to provide power/ground to the LEDs or other devices in the second substrates (e.g., second substrate 110, second substrate 210, second substrate 410, etc.).

In some embodiments, instead of a reconstituted substrate with control devices 106 and singulated LEDs (e.g., red LEDs 112r) such as first substrate 404, 504, or 604 in FIGS. 4-6 respectively, there may be a first reconstituted substrate with control devices 106 hybrid bonded to a second reconstituted substrate with singulated LEDs (e.g., red LEDs 112r). The first reconstituted substrate or wafer may comprise singulated LEDs (e.g., red LEDs 112r) embedded or disposed in a first dielectric layer (e.g., similar to the reconstituted wafer such as first substrate 404, 504, or 604 in FIGS. 4-6 respectively but not including control devices 106). The second reconstituted substrate or wafer may comprise singulated control devices 106 embedded or disposed in a second dielectric layer (e.g., similar to first substrate 404, 504, or 604 in FIGS. 4-6 respectively but not including the red LEDs 112r).

In some embodiments, instead of a reconstituted substrate with control devices 106 and singulated LEDs (e.g., red LEDs 112r) such as first substrate 404, 504, or 604 in FIGS. 4-6 respectively, there may be a wafer comprising control devices 106 hybrid bonded to a reconstituted substrate with singulated LEDs (e.g., red LEDs 112r). The wafer (e.g., control or controller device wafer, device wafer, ROIC wafer, or full wafer) may comprise control devices. The reconstituted substrate or wafer may comprise singulated LEDs (e.g., red LEDs 112r) embedded or disposed in a dielectric layer (e.g., similar to the reconstituted wafer such as first substrate 404, 504, or 604 in FIGS. 4-6 respectively but not including control devices 106).

Although FIGS. 4-6 show a red LED 112r in a bottom layer with a control device 106, any suitable LED may be in a bottom layer (e.g., blue LED, green LED, any suitable type of LED (e.g., any suitable color), or any combination of different types of LEDs). Although FIGS. 4-6 show a control device 106 in a bottom layer, the control device 106 may be in any suitable layer. For example, control device 106 may be in a middle layer. Control device 106 may be in a bottom and middle layer. In some embodiments, control device 106 may be a wafer or a part of the wafer.

FIG. 7 shows a schematic of an example method to form a display through heterogenous pixel integration, where singulated LED 112 from RGB wafers can be integrated to form a composite RGB pixel. In some embodiments, the example method shows forming a substrate (e.g., second substrate 210 of FIGS. 2A-2B).

At block 70, the method includes singulating a wafer to form pixel-size chips or chiplets. For example, a wafer of red LEDs 112r may be placed on a tape frame or temporary carrier 716 and singulated to form red LED chips or chiplets. The singulated LED chips or chiplets may be about 1×1 micron², about 5×5 micron², about 10×10 micron², to about 40×40 micron² or any suitable LED size for a pixel. In some embodiments, any suitable wafer (e.g., wafer of blue LEDs, wafer of green LEDs, wafer of any suitable color, etc.) may be placed on a tape frame and singulated. The method may further include stretching the temporary carrier 716 to space apart neighboring chips or LEDs (e.g., red LEDs 112r), shown at 71.

At block 71, the method includes spacing apart singulated chips or chiplets. In some embodiments, the method of spacing singulated LED chips (e.g., red LEDs 112r) from diced wafers may include separation via dicing tape expansion (e.g., stretching temporary carrier 716). For example, the temporary carrier 716 may be stretched to create uniform spacing between neighboring singulated LEDs (e.g., red LEDs 112r). A spacing of about 1 to 40 microns between neighboring singulated LEDs (e.g., red LEDs 112r) may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 72, the method includes transferring the singulated chips or chiplets to a carrier substrate. For example, red LEDs 112r are transferred to a carrier substrate 720 via bonding or adhesive. Before or after transferring, diffusion regions may be removed from the LEDs and first electrodes 123 may be formed. In some embodiments, both electrodes (e.g., first and second electrodes) may be formed to the LEDs based on the design. The method may include forming a reflective layer 118 over the plurality of singulated LED (e.g., red LEDs 112r). The reflective layer 118 may comprise a reflective metal (e.g., Ag, Au, or Al, etc.) or DBR coatings. One or more dielectric layers (e.g., adhesion, isolation, passivation, barrier, etc.) may be deposited before and/or after the reflective layer 118 is formed. In some embodiments, the reflective layer may comprise of a distributed Bragg reflector. In some embodiments, a light-absorbing layer may be disposed or positioned between adjacent LEDs 112r. The light-absorbing layer comprising a light-absorbing material may be disposed between the reflective layer 118 and a dielectric layer 214. The light-absorbing material may significantly reduce optical crosstalk between neighboring LEDs 112r. In some embodiments, the light-absorbing material comprises a metallic, resin, or polymer material.

At block 73, the method includes forming a reconstitution dielectric over the singulated chips or chiplets. For example, a dielectric layer 214 is formed over the reflective layer 118. The dielectric layer 214 may comprise silicon oxide or a suitable dielectric material tuned to transmit a specific wavelength range (e.g., corresponding to a color of light emitted from an LED of bonded adjacent substrate behind/below dielectric layer 214).

At block 74, the method includes forming electrical connectors to the chip or chiplets. For example, electrical connectors 126 are formed to contact the electrodes 123 of red LEDs 112r. The method may include forming vias 124 through the dielectric layer 214. The vias 124 may enable electrical connections through the dielectric layer 214 to neighboring substrates via hybrid bonding. The electrical connectors 126 and vias 124 may comprise a same or different material and may be any suitable conductive material such as those described in the present disclosure. In some embodiments, the method of forming the electrical connectors 126 and vias 124 may comprise depositing or coating a suitable adhesion layer over a patterned cavity corresponding to the electrical connector 126 and/or vias 124, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric layer 214. In some embodiments, the connectors 126 and vias 124 may comprise wirebonds, formed by wirebonding operations. In other embodiments, the connectors 126 and vias 124 may be formed by 3D printing methods or screen printing methods.

At block 75, the method includes forming a direct bonding interface (DBI) layer (e.g., bottom DBI layer). For example, the method comprises forming a redistribution layer 130 comprising conductive features or bond pads 122 and interconnects 132 in a dielectric layer.

At block 76, the method includes transferring the reconstituted wafer to another substrate. For example, the method includes transferring the reconstituted singulated red LEDs 112r and redistribution layer 130 to substrate 722 (e.g., another carrier or a target wafer) and removing the first carrier 720. In some embodiments, the reconstituted wafer comprising singulated red LEDs 112r can be transferred to or hybrid bonded to another reconstituted wafer (comprising LEDs and/or control device 106) or another wafer comprising control devices 106 (e.g., control or controller device wafer, device wafer, ROIC wafer, full wafer, etc.). The method may include forming second electrodes 732 of the LEDs 112r. The method may include forming another DBI layer (e.g., top DBI layer). For example, the method includes forming a redistribution layer 730 comprising interconnects 132 and bond pads 122 in a dielectric layer.

In some embodiments, the method shown in FIG. 7 can be modified to form any suitable substrates such as those mentioned in the present disclosure. For example, at block 72, method may include multiple transfer steps, where different types of LEDs (e.g., singulated wafer of red LEDs, singulated wafer of green LEDs, singulated wafer of blue LEDs, etc.) and/or singulated control devices may be transferred. For example, the method may be modified to form a reconstituted wafer or layer comprising at least two LEDs that each emit a different color of light from the other (e.g., red and blue, green and blue, red and green, etc.). For example, the method may be modified to form a reconstituted wafer or layer comprising at least three LEDs that each emit a different color of light from the other (e.g., red, green, blue, etc.). For example, the method may be modified to form a reconstituted wafer or layer comprising at least one type of LED emitting a color of light (e.g., red, green, or blue) and a control device.

In some embodiments, the method includes hybrid bonding to electrically connect each control device to one or more of the LEDs to form a pixel. For example, at block 76 the substrate 722 may be a target substrate (e.g., first substrate 204 of FIGS. 2A-2B) and the reconstituted wafer may be one or more second substrates (e.g., second substrates 210 of FIGS. 2A-2B). The second substrate 210 may be hybrid bonded to additional second substrates 210 (e.g., via redistribution layer 730) and the second substrate 210 may be hybrid bonded to a first substrate 204 (e.g., via redistribution layer 130). Hybrid bonding the first substrate (e.g., first substrate 204) and second substrates (e.g., second substrates 210) may electrically connect a control device 106 to one or more LEDs of the second substrates. Each control device and the one or more LEDs electrically connected thereto may form a pixel.

In some embodiments, where there are more than one stacked layer, the display may further comprise light guides. For example, the method may include forming deep-trench isolation with metal fill that guides light emitted from the LEDs of at least of the first substrates or the second substrate to a surface of the display. For example, the method may include forming channels with metal coatings to form light guides. In some embodiments, the method may include forming a dielectric fill on the metal coatings in the channels.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 1B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 1A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

Embodiments herein may provide for integrated visible and infrared image sensors and methods of forming the same. The image sensor may be an integrated visible sensor device and infrared sensor device at a pixel level capable of detecting both visible (VIS) and short-wave infrared (SWIR) wavelengths (e.g., 380-700 nm and 700-2600 nm respectively). In some embodiments, the image sensor may be formed by stacking and/or bonding reconstituted substrates.

High volume consumer, security, industrial and automotive applications may prefer detection of both VIS and SWIR wavelengths. Multiple cameras (e.g., both VIS and SWIR camera) can be used with different optical paths and optical components to detect both VIS and SWIR wavelengths, which may be challenging, expensive, and bulky (e.g., increasing the overall spatial footprint of a device). Use of multiple cameras may also result in design challenges related to form factor, weight, and thermal management. Typical visible sensor pixels (e.g., CMOS pixels) may be smaller (e.g., about 1-5 microns in size) in comparison to IR sensor pixels (e.g., SWIR pixels, about 10-40 microns in size), which may complicate data merging between two captured images at a pixel level.

Advantageously, the image sensors and manufacturing methods described herein may provide for a device structure capable of detecting both visible and SWIR wavelengths within one image sensor or camera, reducing or eliminating the need of multiple image sensors or cameras. The manufacturing methods may provide for reduced manufacturing costs and manufacturing time compared to conventional pick-and-place manufacturing. The integration of VIS and IR sensors (e.g., SWIR sensors) within a pixel layout of an integrated image sensor may enable simpler post-processing.

In some embodiments, SWIR sensors may comprise InGaAs. An InGaAs sensor may have a spectral response between about 900-2600 nm. A desired wavelength response of an InGaAs sensor may be defined by adjusting InAs and GaAs percentage relationships. In some embodiments, SWIR sensors comprise other materials such as PbSe, InSb, or Hg₁₋ₓCdₓTe.

In some approaches, SWIR sensors may comprise multiple stacks of InGaAs and InP. The multiple stacks may enable photons to be absorbed and generated charge carriers to be subsequently collected and converted into an electrical signal. These stacked structures (e.g., multiple stacks of InGaAs and InP layers) may be designed to have a desired spectral response (e.g., SWIR wavelength range). For example, a SWIR sensor may comprise a top n-InP layer, an intermediate n-InGaAs layer, and a bottom n-InP layer. The top n-InP layer may enable only a particular wavelength absorption (e.g., about 0.4-1.7 microns). The intermediate n-InGaAs layer may act as the main absorption layer. The bottom n-InP layer may act as a collection layer. The stacked n-InP, n-InGaAs, n-InP layers may be disposed on and communicatively coupled to an ROIC.

In some approaches, SWIR sensors may comprise a germanium on silicon (Ge-on-Si) structure. Ge may absorb SWIR wavelengths, and Si may absorb visible wavelengths. Ge may be epitaxially grown on Si.

In some approaches, SWIR sensors may comprise quantum dots. For example, a quantum dot (QD)-SWIR sensor may comprise nanoparticles of a SWIR-absorbing material (e.g., PbS) tuned to absorb a specific wavelength or range of wavelengths disposed on an ROIC (e.g., silicon ROIC chip).

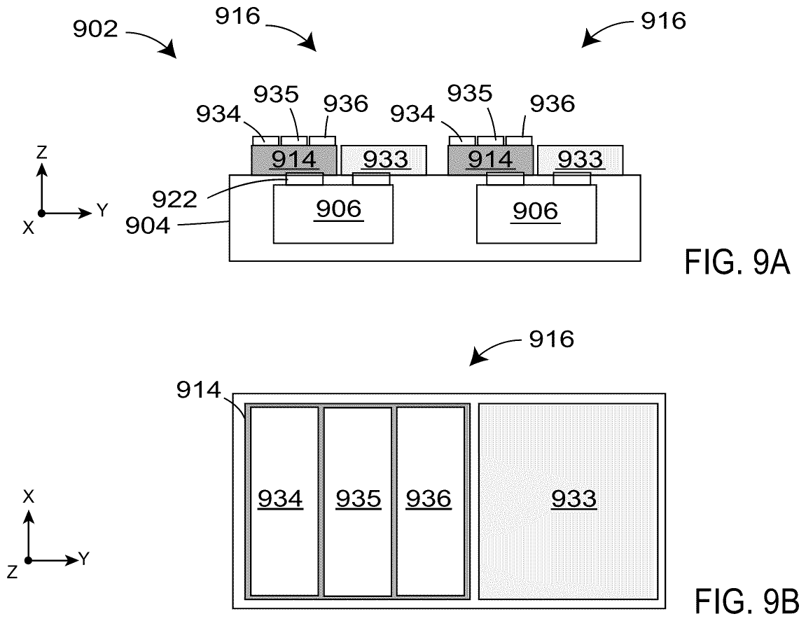

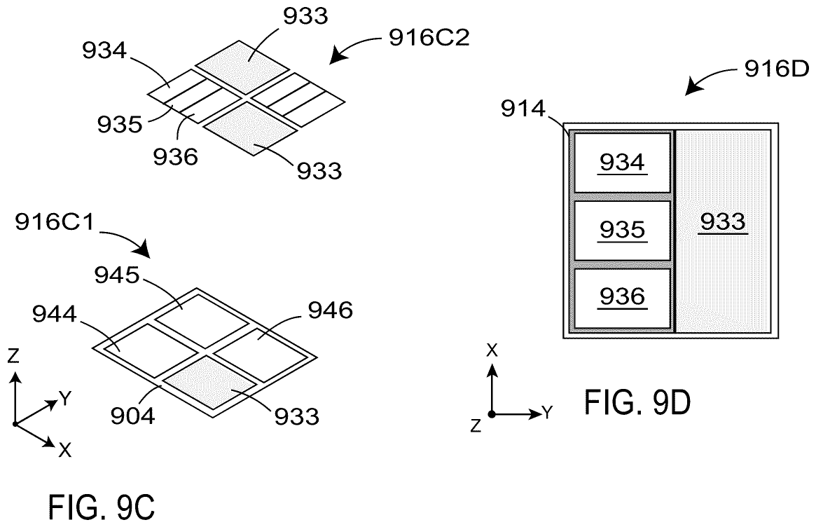

FIG. 9A shows a cross-sectional view of an image sensor device 902, in accordance with some embodiments of the present disclosure. The image sensor device 902 includes a substrate 904 comprising one or more control devices 906, one or more visible sensor devices 914, and one or more infrared sensors 933. Each control device 906 may be electrically connected to at least one visible sensor device 914 and at least one infrared sensor 933. The visible sensor devices 914 and infrared sensors 933 may be directly hybrid bonded 922 to the substrate 904 or a layer deposited on the substrate 904.

In some embodiments, the substrate 904 is a reconstituted substrate. The reconstituted substrate may comprise singulated ROIC chiplets or singulated control devices (e.g., control devices 906) disposed in a dielectric layer (e.g., comprising any suitable dielectric material such as those mentioned in the present disclosure). The visible sensor devices 914 and infrared sensors 933 may be directly hybrid bonded 922 to a reconstituted substrate.

In some embodiments, the substrate 904 is a wafer comprising control devices, processors, or ROICs. For example, a control device wafer (e.g., processor wafer, ROIC wafer) comprising a plurality of control devices 906 (e.g., processors, ROICs) is used in place of the substrate 904, and the visible sensor device 914 and the infrared sensor 933 may be directly hybrid bonded to a control device wafer (e.g., processor wafer, ROIC wafer).

In some embodiments, the substrate 904 comprises a dielectric material. The dielectric material may be any suitable dielectric material such as dielectric materials mentioned in the present disclosure. For example dielectric material may comprise oxides, nitrides, oxynitrides, carbonitrides, and oxycarbonitrides, silicon oxide, silicon nitride, silicon oxynitride, silicon carbonitride, silicon oxycarbonitride, non-conductive material such as a dielectric material or an undoped semiconductor material, such as undoped silicon, which may include native oxide, silicon oxide, silicon nitride, silicon carbide, low K dielectric materials, SiCOH dielectrics, diamond-like carbon or a material comprising a diamond surface. For example the substrate 904, the visible sensor device 914 and the infrared sensor 933 may comprise materials used for bonding layer 808a and 808b of FIG. 8B.

In some embodiments, the control devices 906 may be configured to process charge created by the sensors. For example, the charge created by a photo-detector (e.g., SWIR or visible sensor) is converted to a voltage signal and passed on to the output amplifier through an array of row-select and column-select switches. Furthermore, an analog to digital convertor (ADC) may be formed on a semiconductor layer to digitize the amplified signal. To perform readout, the pixel or sensor values of a given row are transferred in parallel to a set of storage capacitors and then, these transferred pixel or sensor values are read out sequentially. In one approach, the image sensor device may comprise amp transistors, select transistors, reset transistors, signal lines, ADC, pixel select switches (or row/column selects), memory blocks, capacitors, etc. to form an image sensor circuit either disposed in the substrate 904 and/or disposed in the layer comprising the visible sensor device 914 and the infrared sensor 933. In some embodiments, pixel or sensor transistors may be a part of an image processor device (e.g., control device 906).

The pixel sensor architecture may be one of several types. In an active-pixel sensor (APS) architecture, each pixel location contains not only the photodiode or sensor but also an amplifier or multiple sensors and an amplifiers for each sensor. A simpler architecture like passive-pixel sensor (PPS) may also be implemented within the semiconductor layer that does not integrate an amplifier into each pixel. In a digital-pixel sensor (DPS) device architecture, each pixel or sensor may have its own analog-to-digital converter and memory block which allows the digital values proportional to light intensity.

In some embodiments, the visible sensor device 914 comprises a plurality of visible sensors, each visible sensor corresponding to a respective color filters. For example, the visible sensor device 914 comprising at least three color filters 934, 935, and 936 (e.g., red, green and blue) may have a single sensor disposed under each color filter to accept a respective color of light. For example, the visible sensor device 914 may be a singulated chip comprising a plurality of sensors, each sensor being patterned with corresponding electrodes to each sensor. In some embodiments, the visible sensor device 914 may be a high resolution visible sensor device wherein each color filter may correlate to a plurality of sensors on the visible sensor device 914.

In some embodiments, the visible sensor device 914 comprises at least a first, second, and third visible sensor with corresponding color filters 934, 935, and 936. In some embodiments, the control device 906 may include a processor capable of receiving and differentiating electrical signals sent by the visible sensor device 914 and the infrared sensor 933. In some embodiments, each sensor on the visible sensor device 914 and the infrared sensor 933 may be electrically coupled to the control device 906 so that each sensor may be read.

In some embodiments, the visible sensor device comprises one or more silicon photodetectors (e.g., Si sensors, VIS sensors) capable of sensing light in the visible wavelengths (e.g., 380-700 nm or 380-780 nm). In some embodiments, the visible sensor device comprises a plurality of layers, for example a silicon layer, an epitaxial layer, a passivation layer, a bonding layer (e.g., described by FIG. 8A), and an anti-reflective coating. The layers may enhance the ability of the sensor to detect visible light by improving photon absorption and reducing surface recombination.

In some embodiments, the infrared sensor 933 detects infrared (IR) wavelengths. For example, the infrared sensor 933 may be a short-wave infrared (SWIR) sensor and may detect wavelengths in a range of about 0.7-2.5 μm. In some embodiments, the infrared sensor 933 may detect wavelengths in any suitable wavelength range (e.g., about 780-1400 nm, about 1400-3000 nm, about 700 nm-1700 nm or 2500 nm, about 900-1700 nm or 2500 nm, about 1000-2500 nm, etc.). In some embodiments, infrared sensor 933 comprises InGaAs. In some embodiments, the infrared sensor 933 comprises PbSe, InSb, HgCdTe or any combination thereof.

FIG. 9B shows a top-down example view of the pixel layout in an image sensor device 902, in accordance with some embodiments of the present disclosure. In some embodiments, FIG. 9B is a top-down view a single pixel illustrated in FIG. 9A. For example, the pixel 916 on the image sensor device 902 comprises RGB color filters 934, 935, and 936 disposed over a visible sensor device 914 and an infrared sensor 933 adjacent to the visible sensor device 914.

FIGS. 9C-9D show example pixel layouts of an image sensor, in accordance with some embodiments. For example, the example pixel layouts as shown in FIGS. 9C and 9D may be applied to an image sensor device 902 in place of the pixel layout shown in FIGS. 9A and 9B.

FIG. 9C shows a top-down, isometric view of example pixel layouts in an image sensor device, in accordance with some embodiments of the present disclosure. The pixel configuration 916C1 comprises visible light sensors 944, 945, and 946 and an infrared sensor 933. The visible light sensors 944, 945, and 946 may be singulated visible light sensors (e.g., Si sensor) each with a respective color filter (e.g., RGB color filters 934, 935, and 936). In some embodiments, in place of the visible light sensors 944, 945, and 946, a visible sensor device 914 may be disposed under the RGB color filters 934, 935, and 936 (not shown) and the infrared sensor 933. The infrared sensor 933 may comprise an absorbing layer on top to prevent visible light from being transmitted through the infrared sensor 933 to contact the visible light sensor 914.

In some embodiments, an alternative pixel configuration 916C2 may comprise two infrared sensors 933 and two visible light sensor devices 914 each comprising at least three RGB color filters. In some embodiments, a visible sensor device 914 may be disposed under the RGB color filters 934, 935, and 936 and the infrared sensors 933. The infrared sensors 933 may each comprise an absorbing layer on top to prevent visible light from being transmitted through the infrared sensor 933 to contact the visible light sensor 914.

FIG. 9D presents a top-down view of an example pixel layout in an image sensor device, in accordance with some embodiments of the present disclosure. The pixel configuration 916D comprises RGB color filters 934, 935, and 936 disposed over a visible light sensor device 914 and an infrared sensor 933 adjacent to the visible sensor device.

In some embodiments, although three color filters (e.g., RGB color filters) are shown in FIGS. 9A-9D and other embodiments described in the present disclosure, any suitable number of color filters may be used (e.g., two, three or more), and any suitable type of color filter may be used (e.g., same or different wavelength range, any suitable wavelength range). For example, four color filters may be used such as two green, a red, and a blue color filter (e.g., Bayer filter configuration). Although these embodiments indicate RGB color filters (e.g. RGB color filters 934, 935, and 936) disposed over one visible light sensor device 914, it is understood that the photo carriers generated by portion of sensor devices 914 underneath each of the color filters are isolated by inter-pixel separations (e.g. physical barrier structures like deep trench isolations) and processed or read separately by the processor or controller. It is also understood that any orientation of visible sensor devices 914 (and its filters) and infrared sensor 933 may also be implemented.

In some embodiments, although an infrared sensor 933 is shown in FIGS. 9A-9D and other embodiments described in the present disclosure, an infrared sensor device may be used in place of an infrared sensor. The infrared sensor device may comprise a plurality of infrared sensors, and each infrared sensor may detect a same wavelength range or different wavelength range. In some embodiments, a two-color infrared photodetector may be used in place of the infrared sensor 933.

In some embodiments, a sensor device for detecting visible wavelengths (e.g., Si die) and a sensor for detecting SWIR wavelengths (e.g., InGaAs die) is die to wafer (D2W) bonded to a processor chip (e.g., Si processor chip or wafer, ROIC chip or wafer, processor chip or wafer). The CTE of InAs may be about 4.52 ppm/° C., and the CTE of GaAs may be about 5.73 ppm/° C. In some embodiments a bonded die or pixel may be thin and tiny, reducing CTE mismatch issues with Si. In some embodiments, the combined footprint of the visible sensor devices is similar or smaller than the footprint of infrared sensor 933. In some embodiments, the footprint at least one of the color filters over the visible sensor devices is similar or smaller than the footprint of infrared sensor 933.

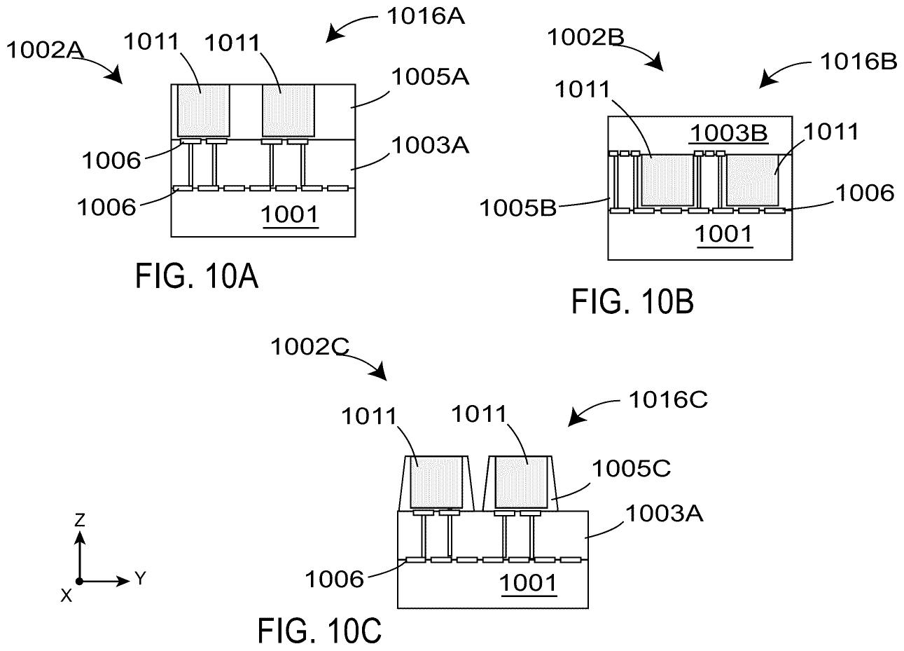

FIGS. 10A-10C show cross-sectional views of example image sensor devices, in accordance with some embodiments of the present disclosure. The image sensor devices shown in FIGS. 10A-10C may detect light in both visible and IR wavelengths (e.g., SWIR wavelengths).

FIG. 10A shows an image sensor device 1002A comprising a first substrate 1001, a second substrate 1003A disposed on the first substrate 1001, and a third substrate 1005A disposed on the second substrate 1003A. In some embodiments, the first substrate 1001 may be similar to substrate 904 as described above in relation to FIG. 9A. For example, the first substrate 1001 may be a control device wafer (e.g., processor wafer, ROIC wafer) or a reconstituted substrate. In some embodiments, the second substrate 1003A may be a VIS image sensor wafer (e.g., silicon image sensor wafer or die) comprising a plurality of visible sensors (e.g., silicon photodiodes, CMOS sensors) to detect light within the visible spectrum (e.g., 380-700 nm or 380-780 nm). In some embodiments, the first substrate 1001 is a CMOS detector substrate (e.g., CMOS wafer, CMOS image sensor wafer a comprising plurality of CMOS detectors) and may comprise pixels (e.g., photodetector or CMOS photodiodes) about 1-5 μm in size. The second substrate 1003A may comprise a color filter layer, a metal layer, and a photodiode layer. The color filter layer may comprise patterned RGB color filters or any suitable number or type of color filters to separate color information from the light. The metal layer may comprise electrodes wiring to connect individual photodiodes. The photodiode layer may collect light and convert it into electrical charges. In another approach, the color filters may be band filters capable of filtering a band of IR wavelengths (e.g., 0.7-2.5 μm). In some embodiments, each photodiode of the visible image sensor may include a barrier (e.g., deep trench isolation or DTI) between each neighboring photodiode. In some embodiments, the third substrate 1005A is a reconstituted substrate comprising singulated infrared sensors (e.g., infrared sensors 1011) disposed in a dielectric material. The dielectric material may comprise an oxide material which is transparent to visible light (e.g., visible spectrum, visible wavelength(s) or range of interest) or any suitable material that is transparent to visible light, and light may pass through the dielectric material to reach the second substrate 1003A (e.g., visible sensors of the second substrate 1003A). In some embodiments, the infrared sensors 1011 are SWIR sensors (e.g., InGaAs sensors) or any suitable SWIR or IR sensors as described in the present disclosure. In some embodiments, the infrared sensor 1011 (e.g., SWIR, InGaAs detector) may comprise one or more pixels (e.g., sensors or photodetectors) of about 5-40 μm or about 10-40 μm in size.

In some embodiments, the first substrate 1001 and the second substrate 1003A each comprise respective bond pads 1006 (e.g., conductive features) embedded in the material (e.g., material layer) of the respective substrates. For example, the first substrate 1001 and the second substrate 1003A may each comprise bond pads 1006 disposed in a dielectric layer (e.g., a redistribution layer on a semiconductor or silicon substrate, wafer, or material layer). The second substrate 1003A may be attached (e.g., bonded, directly bonded, hybrid bonded) to the first substrate 1001. For example, bond pads 1006 of the second substrate 1003A (e.g., visible image sensor wafer) may be directly bonded (e.g., via direct metal bonds, etc.) to bond pads 1006 of the first substrate 1001 (e.g., processor wafer, reconstituted wafer of singulated control devices, etc.), and portions of a dielectric layer of the second substrate 1003A may be directly bonded (e.g., via direct dielectric bonds) to portions of a dielectric layer of the first substrate 1001. The bond pads 1006 may comprise any suitable conductive material. For example, a conductive material may include metals such as copper or copper alloys, nickel, aluminum, or alloys, conductive oxide material such as indium tin oxide (ITO). The dielectric layer may comprise any suitable dielectric material such as those mentioned in the present disclosure.

In some embodiments, the substrate 1005A is a reconstituted substrate comprising a plurality of singulated infrared sensors 1011 disposed in a dielectric material. The dielectric material may comprise any suitable dielectric material such as those mentioned in the present disclosure. In some embodiments, each singulated infrared sensors 1011 is included in a corresponding pixel 1016A on the image sensor device 1002A. For example, FIG. 10A shows two pixels, each singulated infrared sensors 1011 corresponding to a respective pixel 1016A of the sensor device 1002A. In some embodiments, each the infrared sensor 1011 and the Si-sensor may comprise a plurality of subpixels.

In some embodiments, the third substrate 1005A and the second substrate 1003A each comprise respective bond pads 1006 (e.g., similar or same as described above in relation to the second substrate 1003A or first substrate 1001) embedded in the material of each respective substrates. For example, the second substrate 1003A may comprise bond pads 1006 disposed in a dielectric layer (e.g., a redistribution layer on a semiconductor or silicon substrate, wafer, or material layer). The bond pads 1006 may comprise any suitable conductive material. For example, a conductive material may include metals such as copper or copper alloys, nickel, aluminum, or alloys, conductive oxide material such as indium tin oxide (ITO). The dielectric layer may comprise any suitable dielectric material such as those mentioned in the present disclosure. In some embodiments, the third substrate 1005A is a reconstructed substrate comprising singulated infrared sensors 1011 disposed in a dielectric material. In some embodiments, the singulated infrared sensors 1011 comprise InGaAs. In some embodiments, the dielectric material of the third substrate 1005A comprises a material that allows for the transmittance of visible wavelengths of light. For example, the dielectric material of the third substrate 1005A may comprise oxide material transparent to visible light. Metallization (e.g., vias, traces, interconnects, conductive features, bond pads, etc.) formed in the third substrate 1005A and second substrate 1003A may be disposed in a shadow of a die or singulated infrared sensor (e.g., overlapping with a footprint of sensor 1011) to enable light to reach photodiodes in the second substrate 1003A.

FIG. 10B schematically illustrates an example image sensor 1002B, in accordance with some embodiments of the present disclosure. FIG. 10B shows the image sensor device 1002B comprising a first substrate 1001, a third substrate 1005B disposed on the first substrate 1001, and a second substrate 1003B disposed on the third substrate 1005B. The image sensor 1002B may be similar (e.g., have same or similar features) to the image sensor 1002A described above, and therefore the description of similar features is omitted for brevity. In some embodiments, the second substrate 1003B, third substrate 1005B, and pixel 1016B of FIG. 10B corresponds to the second substrate 1003A, third substrate 1005A, and pixel 1016B respectively of FIG. 10A. For example, second substrate 1003B may be the same as second substrate 1003A except that second substrate 1003B does not include vias and is disposed on top of third substrate 1005B. Additionally, in some embodiments, a micro lens array may be disposed over the third substrate 1003B to direct light towards the photodiode layer of the third substrate 1003B. Third substrate 1005B may be the same as third substrate 1005A except that is disposed below the second substrate 1003B and includes vias. Additionally, in some embodiments, the second substrate 1003B may be transparent to infrared wavelengths (e.g., silicon may be transparent above about 1.1 microns, image sensor comprising silicon) enabling the transmittance of infrared wavelengths through the second substrate 1003B to the third substrate 1005B and singulated infrared sensors 1011 (e.g., to be absorbed by the infrared sensors). In some embodiments, each respective surface of each respective substrate may comprise an anti-reflective coating. For example, the second substrate 1003B may comprise anti-reflective coatings to reduce Fresnel loss at the surface of each respective light detection layers. In some embodiments, the third substrate 1005B may comprise anti-reflective coating for the infrared light. Silicon may be transparent to wavelengths above 1.1 microns, so SWIR wavelengths may be absorbed in the IR sensors.

FIG. 10C schematically illustrates an embodiment of an image sensor 1002C, in accordance with some embodiments of the present disclosure. In some embodiments, the image sensor device 1002C of FIG. 10C is similar to the image sensor device 1002A of FIG. 10A, except that the third substrate 1005C comprises patterned dielectric material to expose top portions of the second substrate 1003A. In some embodiments, the third substrate 1005C is a reconstituted wafer of SWIR sensors. In some embodiments, the third substrate 1005C and pixel 1016C of FIG. 10C may correspond to (e.g., may be the same or similar to) the third substrate 1005A and pixel 1016A respectively of FIG. 10A, except that portions of third substrate 1005A such as portions of the dielectric material between infrared sensors 1011 are removed from the third substrate 1005A to form the third substrate 1005C. In some embodiments, patterning dielectric material for the third substrate 1005C may include etching the third substrate 1005A. For example, a window (e.g., opening) may be etched in the reconstitution dielectric of the third substrate 1005A to expose a bottom sensor (e.g., a photodiode of second substrate 1003A).

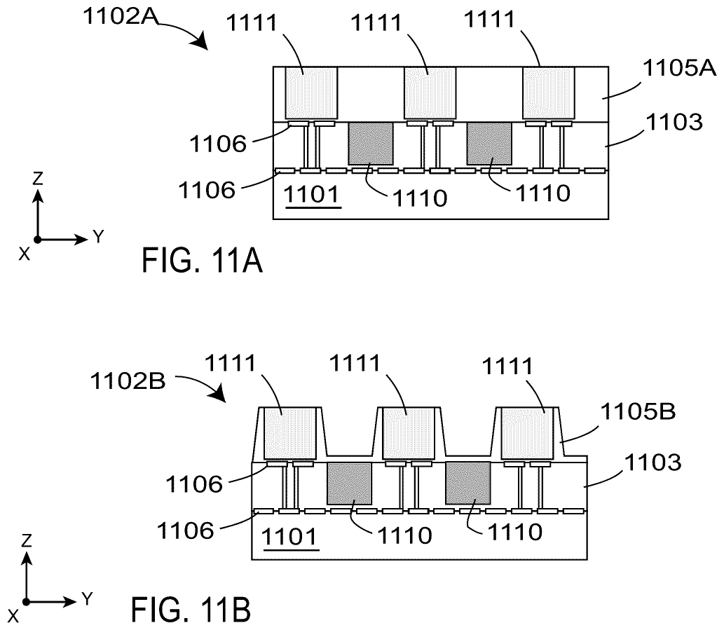

FIGS. 11A-11B depict example cross-sectional views of image sensor devices 1102A and1102B, in accordance with some embodiments of the present disclosure. In some embodiments, as illustrated in FIG. 11A, the image sensor device 1102A may comprise a first substrate 1101, a second substrate 1103, and a third substrate 1105A arranged in a stack. In some embodiments, the image sensor device 1102A is a VIS/SWIR sensor capable of detecting light in both visible and IR or SWIR wavelengths. In some embodiments, the first substrate 1101 is a ROIC/processor. In some embodiments, the first substrate 1101 is a reconstituted wafer comprising singulated ROICs, similar to those as exemplified in FIG. 9A.

In some embodiments, the second substrate 1103 is a reconstituted wafer comprising singulated visible light sensors 1110 (e.g., Si-sensors, Si photodiodes, CMOS sensors, etc.). In some embodiments, the singulated visible light sensors 1110 are disposed in a dielectric material of the second substrate 1103. The dielectric material may be any suitable dielectric material such as dielectric materials mentioned in the present disclosure. In some embodiments, the first and second substrate comprise bond pads 1106 embedded in the dielectric material of the respective substrate. In some embodiments, the bond pads 1106 are similar to the bond pads 1006 as described in FIGS. 10A-10C. The first and second substrate may be bonded (e.g., directly bonded, hybrid bonded) as described in the description of FIGS. 8A-8B.

In some embodiments, a third substrate 1105A is disposed over the second substrate 1103. In some embodiments, the third substrate 1105A is a reconstituted wafer comprising singulated infrared sensors 1111 disposed in a dielectric material of the third substrate 1105A. The dielectric material may be any suitable dielectric material such as dielectric materials mentioned in the present disclosure. In some embodiments, the third substrate 1105A and second substrate 1103 are bonded (e.g., directly bonded, hybrid bonded) using method and materials of the bonding described above, for example in FIGS. 8A-8B. In some embodiments, image sensor device 1102A may comprise an alternative stacked configuration, for example, the stack may be arranged in such a way that the third substrate 1105A is stacked on top the first substrate 1101 and the second substrate 1103 may be stacked on top the third substrate 1105A. When the third substrate 1105A is stacked between the second substrate 1103 and the first substrate 1101, the third substrate 1105A may comprise metallization (e.g., vias, etc.) which may be in a shadow or overlapping a footprint of the visible light sensors 1110. Any of the substrates may comprise vias to electrically couple to components (e.g., conductive features, bond pads, control devices) disposed within to the first substrate 1101. For example, the second substrate 1103 may include a via to connect to electrodes of the infrared sensors 1111 in the third substrate 1105A (e.g., provide power/ground, detect a signal, etc.). Similarly, the first substrate 1101 may comprise a via to provide power/ground to the visible light sensor 1110 disposed in the second substrate 1103. When the second substrate 1103 is stacked on top of the third substrate 1105A, the dielectric material of the second substrate 1103 may be a material that is transparent to IR light (e.g., IR spectrum, IR wavelength(s) or range of interest), and light may pass through the dielectric material of the second substrate 1103 to reach the third substrate 1105A (e.g., infrared sensors in the third substrate 1105A). For example, the dielectric material that is transparent to IR light may comprise silicon oxide, special grade silicon oxide for transparency in IR wavelengths, aluminum oxide, hafnium oxide, magnesium fluoride used in combination with an oxide, any suitable oxide that is transparent to IR light, or combination thereof.

FIG. 11B schematically illustrates an embodiment of an image sensor 1102B, in accordance with some embodiments of the present disclosure. In some embodiments, the image sensor device 1102B may comprise a first substrate 1101 a second substrate 1103 and a third substrate 1105B arranged in a stack. The image sensor 1102B may be similar (e.g., have same or similar features) to the image sensor 1002A described above, and therefore the description of similar features is omitted for brevity. In some embodiments, the third substrate 1105B may be the same as the third substrate 1105A of FIG. 11A, except that portions of the third substrate 1105A may be removed in such a way to expose top portions of the second substrate 1103. In some embodiments, removing portions for the third substrate 1105A may include etching the third substrate 1105A to form the third substrate 1105B. Although FIG. 11B shows a portion of a material layer or dielectric material of the third substrate 1105B above a surface of the sensors 1110, in some embodiments the material layer above a surface of the sensors 1110 may be removed, and a surface of sensors 1110 may be exposed. In some embodiments, when surfaces of sensors 1110 are exposed, the material layer or dielectric material of the third substrate 1105B may be a material that is not transparent to visible light (e.g., visible spectrum, visible wavelength(s) or range of interest). In some embodiments, the material layer or dielectric material of the third substrate 1105B may be a material that is transparent to visible light (e.g., visible spectrum, visible wavelength(s) or range of interest). In some embodiments, where the second substrate 1103 is stacked on top of the third substrate 1105A and portions of the second substrate 1103 is removed to expose top portions of the third substrate 1105A, the dielectric material of the second substrate 1103 may be a material that is not transparent to IR light (e.g., IR spectrum, IR wavelength(s) or range of interest). In some embodiments, the material layer or dielectric material of the second substrate 1103 may be a material that is transparent to IR light (e.g., IR spectrum, IR wavelength(s) or range of interest).

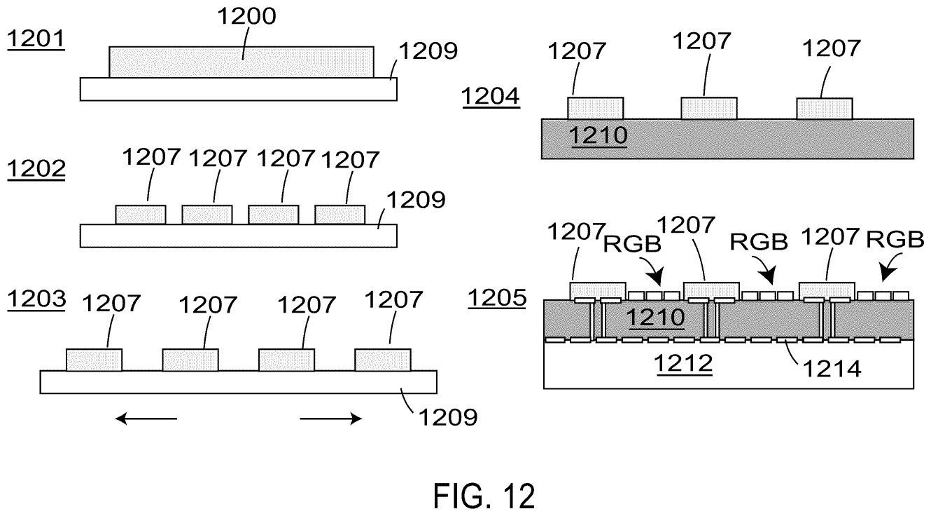

FIG. 12 shows a schematic of an example method to form an image sensor device, capable of detecting both VIS/IR wavelengths through heterogenous pixel integration.

At block 1201, the method includes providing a wafer 1200 on a substrate 1209. For example the wafer 1200 may comprise a plurality of infrared sensors. In some embodiments, wafer 1200 is a monolithic wafer comprising InGaAs sensors. In some embodiments, the substrate 1209 is a carrier substrate (e.g., tape frame carrier).

At block 1202 the method includes thinning and singulating the wafer 1200 to form pixel-size chips or chiplets 1207. For example, a wafer of InGaAs may be placed on a tape frame or temporary carrier (e.g., substrate 1209) and thinned and singulated to form InGaAs chips or chiplets. The singulated IR sensor chips or chiplets may be about 1×1 micron², about 5×5 micron², about 10×10 micron², to about 40×40 micron² or any suitable LED size for a pixel. In some embodiments, any suitable wafer (e.g., wafer of Si-sensor for detecting light in the visible spectra) may be placed on a tape frame and singulated.

At block 1203, the method includes spacing apart the singulated chips or chiplets 1207. In some embodiments, spacing singulated chips or chiplets 1207 (e.g., InGaAs chips, infrared sensors) from diced wafers may include separation via dicing tape expansion (e.g., stretching temporary carrier or substrate 1209). For example, the temporary carrier or substrate 1209 may be stretched to create uniform spacing between neighboring singulated IR sensors. A spacing of about 1 to 40 microns between neighboring singulated IR sensors may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 1204, the method includes transferring the singulated chips or chiplets 1207 to a Si-sensor substrate 1210. For example, IR sensor chiplets are transferred to the Si-image sensor wafer via bonding (e.g., direct bonding, hybrid bonding) or adhesive. In some embodiments, both electrodes (e.g., first and second electrodes) may be formed to the IR sensor and Si-sensor based on the design. One or more dielectric layers (e.g., adhesion, isolation, passivation, barrier, etc.) may be deposited before and/or after the electrodes are formed. In some embodiments, the singulated IR sensors (e.g., chip or chiplets 1207) may be embedded in a dielectric material (e.g., disposed in a reconstitution dielectric) to form a reconstituted substrate, similar to the third substrate 1105A described in FIG. 11A. In some embodiments, a reconstituted substrate, similar to the second substrate 1103 described in FIG. 11A, may be used in place of the Si-sensor substrate 1210.

At block 1205, the method further includes forming electrical connectors to the chip or chiplets 1207 through the Si-sensor substrate 1210. For example, electrical connectors are formed through the Si-sensor substrate 1210 for ROIC/processor substrate 1212 (e.g., similar to substrate 1001 of FIGS. 10A-10C) to contact the electrodes of IR sensor (e.g., chip or chiplets 1207). In some embodiments, the Si-sensor substrate 1210 is bonded (e.g., directly bonded, hybrid bonded) to the ROIC/processor substrate 1212 via bond pads 1214. The method may include forming vias through the Si-sensor substrate 1210 or the dielectric material of the reconstituted Si-sensor. The vias may enable electrical connections through the dielectric material to adjacent substrates via hybrid bonding. The electrical connectors and vias may comprise a same or different material and may be any suitable conductive material such as those described in the present disclosure. In some embodiments, the method of forming the electrical connectors and vias may comprise depositing or coating a suitable adhesion layer over a patterned cavity corresponding to the electrical connector and/or vias, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric material. In some embodiments, the connectors and vias may comprise wirebonds formed by wirebonding operations. In other embodiments, the connectors and vias may be formed by 3D printing methods or screen printing methods.

Though not illustrated, it may be understood that prior to block 1204, the method includes forming a direct bonding interface (DBI) layer (e.g., bottom DBI layer) on the chip or chiplets 1207 or in some embodiments, a reconstituted substrate comprising chip or chiplets 1207 to bond to Si-sensor substrate 1210. For example, the method comprises forming a redistribution layer comprising conductive features or bond pads and interconnects in a dielectric layer.

At block 1205, the method may include transferring color filters (e.g., RGB color filters) for the Si-sensor over the Si-sensor 1210. In some embodiments, the color filters are part of the Si-sensor substrate 1210. For example, color filters may be formed on the Si-Sensor substrate 1210 and may be present prior to attaching chip or chiplets 1207 to Si-sensor substrate 1210 (e.g., block 1204).

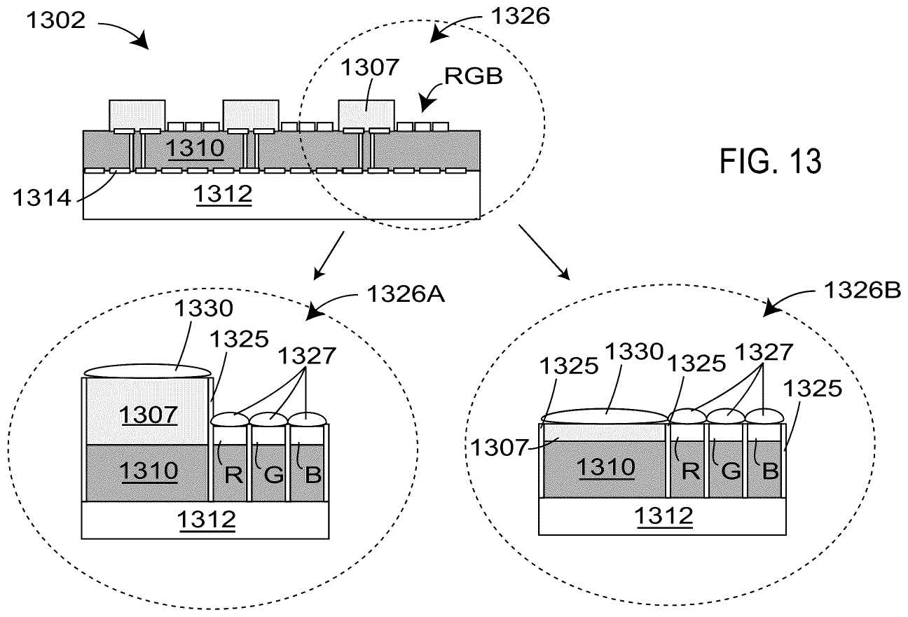

FIG. 13 schematically illustrates an embodiment of an image sensor 1302, in accordance with some embodiments of the present disclosure. FIG. 13 shows an image sensor device comprising a first substrate 1312, a second substrate 1310 disposed over the first substrate 1312 and infrared sensors 1307 disposed over the second substrate 1310. In some embodiments, the first substrate 1312 is similar to substrate 904 as described above in relation to FIG. 9A. For example, the first substrate 1312 may be a control device wafer (e.g., processor wafer, ROIC wafer) or a reconstituted substrate. In some embodiments, the image sensor device 1302 may comprise a first substrate 1312, a second substrate 1310, and an IR sensor 1307 arranged in a stack. In some embodiments, the image sensor device 1302 is a VIS/IR sensor capable of detecting light in both visible and IR (e.g., SWIR) wavelengths. In some embodiments, the first substrate 1312 is a ROIC/processor.

In some embodiments, the second substrate 1310 is similar to substrate 1003A as described above in relation to FIG. 10A or may be similar to substrate 1103 as described above in relation to FIG. 11A. For example, the second substrate 1310 may be a visible image sensor (e.g., Si-sensor) or may be a singulated visible image sensor reconstituted in a dielectric as a monolithic wafer assembly. In some embodiments, the second substrate 1310 is bonded to the first substrate 1312 via bond pads 1314. The bond pads 1314 may be similar to the bond pads 1006 as described in reference to FIGS. 10A-10C. The second substrate 1310 may comprise electrical connects (e.g., vias) that connect an IR sensor 1307 to a control device of the first substrate 1312. In some embodiments, RGB color filters for the Si-sensor are disposed over the Si-sensor, and adjacent to the IR sensor 1307. FIG. 13 shows two different pixel configurations, a first pixel configuration 1326A and a second pixel configuration 1326B derived from a pixel 1326 of an image sensor 1302. The first pixel 1326A illustrates an example in which the IR sensor 1307 is thicker than the color filters (e.g., RGB color filters). In some embodiments, the thickness of the IR sensor 1307 may be thinner than the RGB color filters and in other embodiments, the thickness may be similar, as illustrated in the second pixel 1326B.

In some embodiments, the pixel 1326 comprises a pixel separation 1325 separating the IR sensor from the Si-sensor and RGB color filters on the Si-sensor. In some embodiments, the pixel separation 1325 may separate each the RGB filters on the Si-sensor. The material for the pixel separation may consist of an absorbing dielectric or reflective metal.

In some embodiments, a lens array 1330 and 1327 is disposed over each RGB color filter and IR sensor 1307. In some embodiments, the lens array 1330 and 1327 comprises a single lens for each IR sensor and a single lens for each Si-sensor.

In some embodiments, each pixel 1326 may comprise a top-down pixel layout similar to any of configuration similar to FIGS. 9A-9D. For example, a single pixel of FIG. 13 may be similar to the pixel layout 916C2 of FIG. 9, and a single pixel may comprise two IR sensors 1307 and two Si-sensor devices, each Si-sensor device comprising a respective color filter configuration.

The embodiments discussed above are intended to be illustrative and not limiting. One skilled in the art would appreciate that individual aspects of the displays, display devices, image sensors, display and image sensor device packages, and methods discussed herein may be omitted, modified, combined, and/or rearranged without departing from the scope of the disclosure.

1. A display device comprising:
a first substrate comprising a plurality of singulated control devices embedded in a first dielectric layer; and
a second substrate comprising a plurality of singulated LEDs embedded in a second dielectric layer, wherein the second substrate is directly bonded to the first substrate without an intervening adhesive.

2. The display device of claim 1, wherein each control device is electrically connected to one or more of the LEDs via direct hybrid bonds formed between the first substrate and the second substrate.

3. The display device of claim 2, wherein each singulated control device and the one or more LEDs electrically connected thereto form a pixel.

4. The display device of claim 3, wherein each pixel comprises at least two LEDs that each emit a different color of light from the other.

5. The display device of claim 3, wherein each pixel comprises at least three LEDs that each emit a different color of light from the others.

6. The display device of claim 1, further comprising a reflective layer disposed between each LED and the second dielectric layer.

7. The display device of claim 6, wherein portions of the reflective layer are disposed between adjacent LEDs.

8. The display device of claim 7, further comprising a light absorbing layer comprising a light absorbing material that substantially reduces optical crosstalk between the adjacent LEDs, wherein the light absorbing layer is disposed between the reflective layer and the second dielectric layer.

9. (canceled)

10. The display device of claim 1, wherein the second dielectric layer comprises silicon oxide.

11. A display device, comprising:
a first substrate comprising a plurality of singulated control devices embedded in a first dielectric layer; and
a plurality of second substrates arranged in a stack, each second substrate directly bonded to a vertically adjacent second substrate without an intervening adhesive, wherein each second substrate comprises a plurality of singulated LEDs embedded in a respective second dielectric layer.

12. The display device of claim 11, wherein the LEDs of each of the plurality of second substrates are horizontally offset with respect to the LEDs disposed in a vertically adjacent second substrate.

13. The display device of claim 11, wherein each control device is electrically connected to one or more of the LEDs via direct hybrid bonds formed between the first substrate and an adjacent second substrate.

14. The display device of claim 13, wherein each singulated control device and the one or more LEDs electrically connected to the control device form a pixel.

15. The display device of claim 14, wherein each pixel comprises at least three LEDs that each emit a different color of light from the others.

16. The display device of claim 11, further comprising a first reflective layer disposed between each LED and the respective second dielectric layer.

17. The display device of claim 11, wherein each pixel comprises one or more light guides, each light guide comprising a second reflective layer that directs light emitted from a respective LED to a surface of the display device.

18. The display device of claim 17, wherein each of the one or more light guides further comprises a dielectric fill disposed inward from the second reflective layer.

19. The display device of claim 18, wherein the dielectric fill has a higher optical transmission in a desired color spectrum than the respective second dielectric layer.

20. The display device of claim 16, further comprising a light absorbing material layer disposed between the first reflective layer and the respective second dielectric layer.

21. The display device of claim 11, wherein the respective second dielectric layer comprises silicon oxide.

22-49. (canceled)
